(19) United States
(12) Patent Application Publication
(10) Pub. No.: US 2026/0107555 A1
(43) Pub. Date: Apr. 16, 2026

(54) METHOD OF MANUFACTURING INTEGRATED CIRCUIT DEVICE

(71) Applicant: Samsung Electronics Co., Ltd., Suwon-si (KR)

(72) Inventors: Sungmin KIM, Suwon-si (KR); Yeonsook KIM, Suwon-si (KR); Yoonhee LEE, Suwon-si (KR)

(73) Assignee: Samsung Electronics Co., Ltd., Suwon-si (KR)

(21) Appl. No.: 19/198,773

(22) Filed: May 5, 2025

(30) Foreign Application Priority Data
Oct. 16, 2024 (KR) 10-2024-0141454

(51) Int. Cl. H10D 84/01; H10D 30/01

(52) U.S. Cl. CPC H10D 84/0149; H10D 30/0198; H10D 84/0133

(57) ABSTRACT

A method includes forming a base substrate having a semiconductor substrate having a first dopant concentration, a bottom epitaxial semiconductor layer having a second dopant concentration greater than the first dopant concentration, and a top epitaxial semiconductor layer having a third dopant concentration less than the second dopant concentration, forming a front-end-of-line (FEOL) structure on the top epitaxial semiconductor layer, forming a first back-end-of-line (BEOL) structure on the FEOL structure, removing the semiconductor substrate to expose the bottom epitaxial semiconductor layer, and forming a second BEOL structure to be apart from the first BEOL structure with the FEOL structure therebetween by removing the bottom epitaxial semiconductor layer by wet etching to expose the top epitaxial semiconductor layer and patterning the top epitaxial semiconductor layer.

### CROSS-REFERENCE TO RELATED APPLICATION

This application is based on and claims priority under 35 U.S.C. § 119 to Korean Patent Application No. 10-2024-0141454, filed on Oct. 16, 2024, in the Korean Intellectual Property Office, the disclosure of which is incorporated by reference herein in its entirety.

### BACKGROUND

The inventive concepts relate to methods of manufacturing an integrated circuit device, and more particularly, to methods of manufacturing an integrated circuit device including a backside power delivery network (BSPDN) structure in which a wiring structure is formed on a back side of a substrate.

Due to the advance of electronics technology, integrated circuit devices have been rapidly down-scaled. Therefore, to achieve higher integration while securing functions and operating speeds required by integrated circuit devices, researches for efficiently designing wiring structures are being conducted. In addition, there is a need to develop techniques capable of improving the stability of manufacturing processes of integrated circuit devices and/or improving the reliability of integrated circuit devices obtained as a result thereof by providing uniform flatness of backside surfaces of substrates that are used in the manufacturing processes of the integrated circuit devices having BSPDN structures.

### SUMMARY

An example embodiment of the inventive concepts provide a method of manufacturing an integrated circuit device, the method allowing the stability in a manufacturing process of the integrated circuit device to be improved by providing uniform flatness without a thickness deviation (e.g., relatively uniform flatness with thickness deviation below a certain value) depending on positions in a substrate, when a thinning process for reducing the thickness of the substrate from the back side of the substrate and subsequent processes thereto are performed in the manufacturing process of the integrated circuit device having a backside power delivery network (BSPDN) structure.

According to an example embodiment of the inventive concepts, there is provided a method of manufacturing an integrated circuit device. The method includes forming a base substrate with a structure that comprise a semiconductor substrate having a first dopant concentration, a bottom epitaxial semiconductor layer integrally connected to the semiconductor substrate, the bottom epitaxial semiconductor layer having a second dopant concentration greater than the first dopant concentration, and a top epitaxial semiconductor layer integrally connected to the bottom epitaxial semiconductor layer and having a third dopant concentration less than the second dopant concentration, wherein the semiconductor substrate, the bottom epitaxial semiconductor layer, and the top epitaxial semiconductor layer are sequentially stacked in a vertical direction, forming a front-end-of-line (FEOL) structure on a frontside surface of the top epitaxial semiconductor layer, forming a first back-end-of-line (BEOL) structure on the FEOL structure such that the first BEOL structure is apart from the base substrate in the vertical direction with the FEOL structure therebetween, removing the semiconductor substrate from the base substrate to expose the bottom epitaxial semiconductor layer, and forming a second BEOL structure to be apart from the first BEOL structure in the vertical direction with the FEOL structure therebetween by performing a backside process that includes removing the bottom epitaxial semiconductor layer by wet etching to expose the top epitaxial semiconductor layer and patterning the top epitaxial semiconductor layer.

According to an example embodiment of the inventive concepts, there is provided a method of manufacturing an integrated circuit device. The method includes forming a base substrate with a structure that comprise a semiconductor substrate having a first dopant concentration, a bottom epitaxial semiconductor layer having a second dopant concentration greater than the first dopant concentration, and a top epitaxial semiconductor layer having a third dopant concentration less than the second dopant concentration, wherein the semiconductor substrate, the bottom epitaxial semiconductor layer, and the top epitaxial semiconductor layer are sequentially stacked in a vertical direction, forming a fin-type active region by etching a portion of the top epitaxial semiconductor layer, the fin-type active region including another portion of the top epitaxial semiconductor layer, forming a front-end-of-line (FEOL) structure on the fin-type active region, the FEOL structure including a gate line and a source/drain region, forming a first back-end-of-line (BEOL) structure on the FEOL structure such that the first BEOL structure is apart from the base substrate in the vertical direction with the FEOL structure therebetween, removing the semiconductor substrate from the base substrate to expose the bottom epitaxial semiconductor layer, and forming a second BEOL structure to be apart from the first BEOL structure in the vertical direction with the FEOL structure therebetween by performing a backside process that includes removing the bottom epitaxial semiconductor layer by wet etching to expose a backside surface of the fin-type active region and etching at least a portion of the fin-type active region.

According to an example embodiment of the inventive concepts, there is provided a method of manufacturing an integrated circuit device. The method includes forming a base substrate that includes a Si substrate having a first dopant concentration, a bottom epitaxial Si layer integrally connected to the Si substrate and having a second dopant concentration greater than the first dopant concentration, and a top epitaxial Si layer without germanium (Ge), the top epitaxial Si layer being integrally connected to the bottom epitaxial Si layer and having a third dopant concentration less than the second dopant concentration, forming a fin-type active region by etching a portion of the top epitaxial Si layer, the fin-type active region including another portion of the top epitaxial Si layer, forming a front-end-of-line (FEOL) structure on the fin-type active region, the FEOL structure including a gate line and a source/drain region, forming a first back-end-of-line (BEOL) structure on the FEOL structure such that the first BEOL structure is apart from the base substrate in a vertical direction with the FEOL structure therebetween, bonding a sustain wafer onto the first BEOL structure, removing the Si substrate from the base substrate to expose the bottom epitaxial Si layer while the first BEOL structure is bonded to the sustain wafer, and forming a second BEOL structure to be apart from the first BEOL structure with the FEOL structure therebetween by performing a backside process that includes removing the bottom epitaxial Si layer by wet etching to expose a backside surface of the fin-type active region and etching at least a portion of the fin-type active region, while the first BEOL structure is bonded to the sustain wafer.

### BRIEF DESCRIPTION OF THE DRAWINGS

Example embodiments will be more clearly understood from the following detailed description taken in conjunction with the accompanying drawings in which:

FIG. 1 is a flowchart illustrating a method of manufacturing an integrated circuit device, according to an example embodiment;

FIGS. 2A to 2H are cross-sectional views respectively illustrating a sequence of processes of a method of manufacturing an integrated circuit device, according to an example embodiment;

FIG. 3 is a diagram illustrating an example of a dopant concentration profile in a base substrate used in a method of manufacturing an integrated circuit device, according to an example embodiment;

FIG. 4 is a diagram illustrating an example of a dopant concentration profile in a base substrate used in a method of manufacturing an integrated circuit device, according to an example embodiment;

FIGS. 5A and 5B are cross-sectional views respectively illustrating a sequence of processes of an example of a method of bonding a first back-end-of-line (BEOL) structure and a sustain wafer to each other according to a method of manufacturing an integrated circuit device, according to an example embodiment;

FIG. 6 is a cross-sectional view illustrating a method of manufacturing an integrated circuit device, according to an example embodiment;

FIG. 7 is an example of a planar layout diagram of an integrated circuit device manufactured by a method of manufacturing an integrated circuit device, according to an example embodiment;

FIGS. 8 to 24 are cross-sectional views illustrating a sequence of processes of a method of manufacturing an integrated circuit device, according to an example embodiment, and in particular, FIGS. 8, 9A, 10A, 11A, 12A, 13A, 14, 15, 16, 17, 18, 19, 20, 21, 22, 23, and 24 are cross-sectional views respectively illustrating cross-sectional structures of a region corresponding to a cross-section taken along a line X1-X1′ of FIG. 7, according to the sequence of processes, and FIGS. 9B, 10B, 11B, 12B, and 13B are cross-sectional views respectively illustrating cross-sectional structures of a region corresponding to a cross-section taken along a line Y1-Y1′ of FIG. 7, according to the sequence of processes; and

FIGS. 25 to 29 are cross-sectional views respectively illustrating a sequence of processes of a method of manufacturing an integrated circuit device, according to an example embodiment, and illustrate cross-sectional structures of a region corresponding to the cross-section taken along the line X1-X1′ of FIG. 7, respectively, according to the sequence of processes.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments of the inventive concepts will be described in detail with reference to the accompanying drawings. Like components are denoted by like reference numerals throughout the specification, and repeated descriptions thereof are omitted.

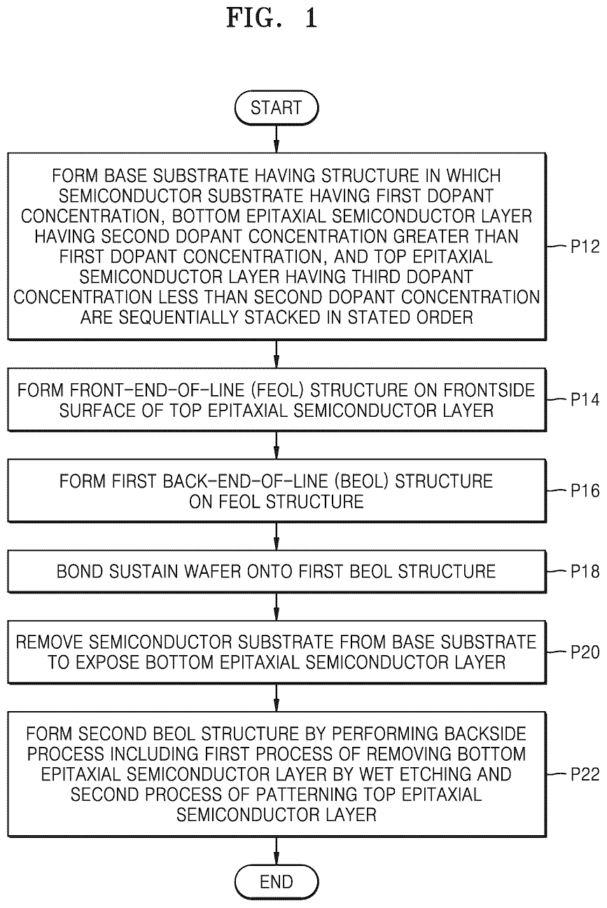

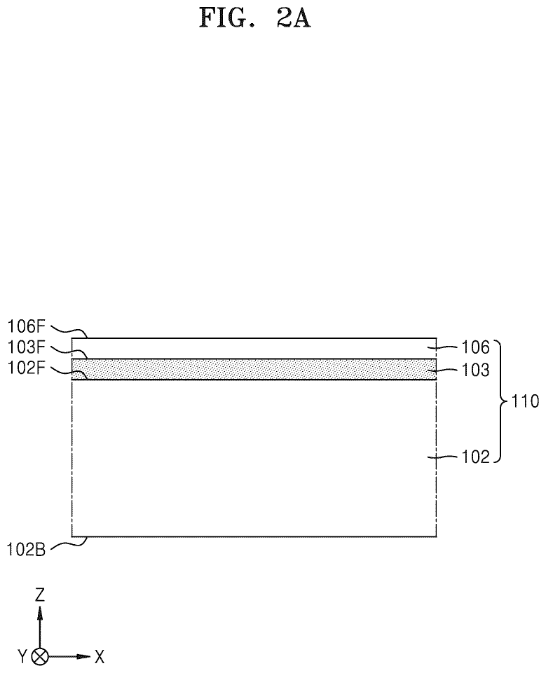

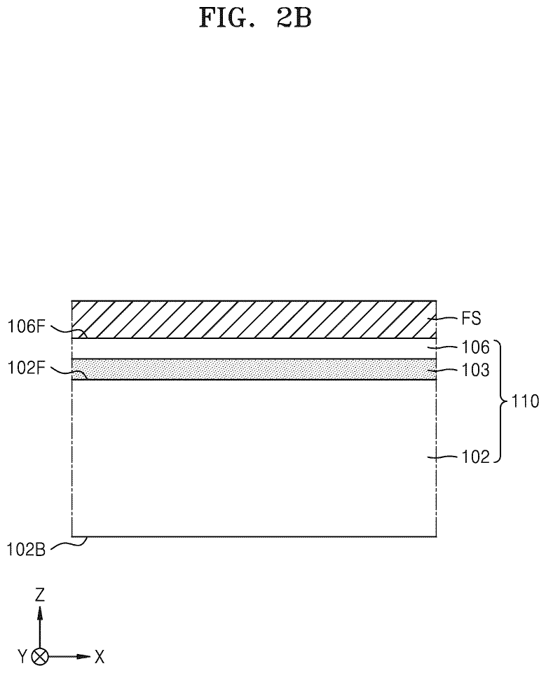

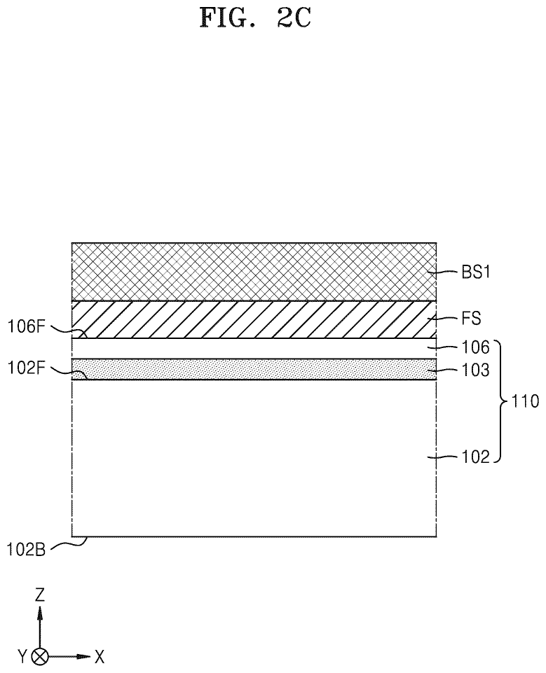

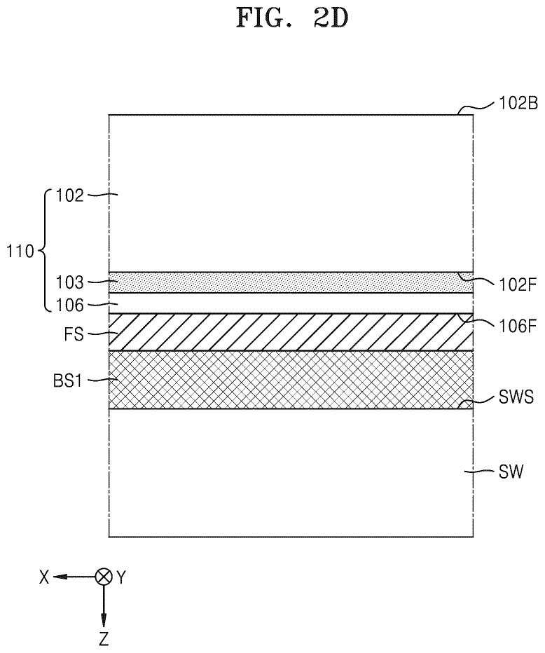

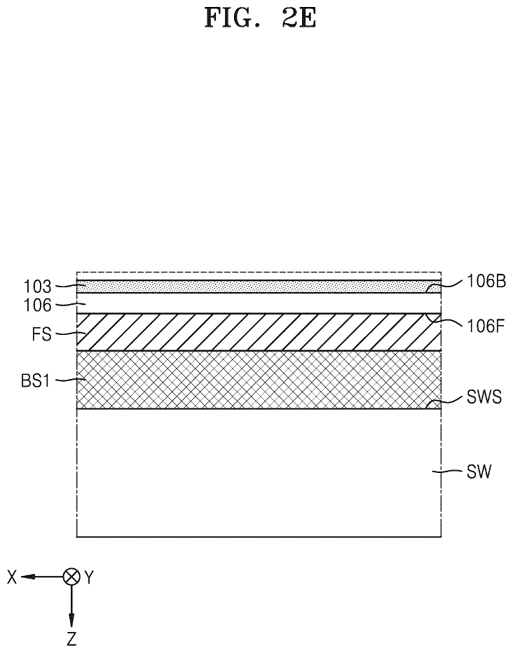

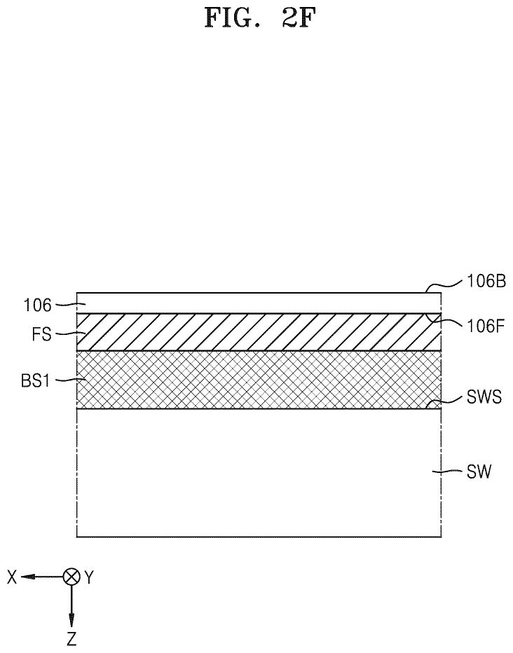

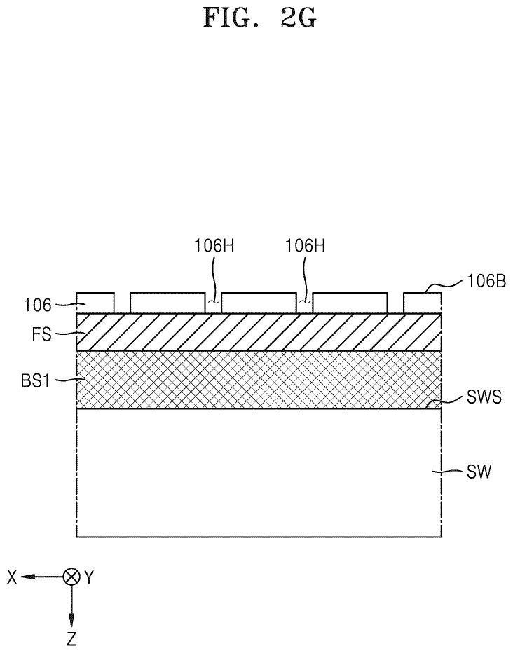

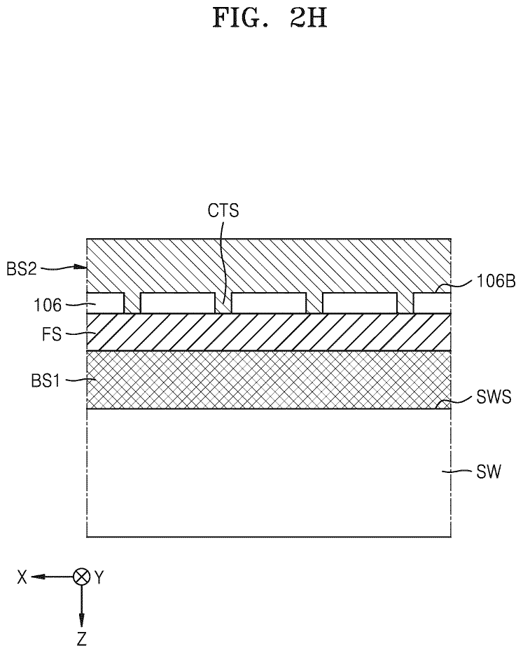

FIG. 1 is a flowchart illustrating a method of manufacturing an integrated circuit device, according to an example embodiment. FIGS. 2A to 2H are cross-sectional views respectively illustrating a sequence of processes of a method of manufacturing an integrated circuit device, according to an example embodiment. A method of manufacturing an integrated circuit device, according to an example embodiment, will be described with reference to FIGS. 1 and 2A to 2H.

Referring to FIGS. 1 and 2A, in process P12, a base substrate 110 is formed. The base substrate 110 has a structure in which a semiconductor substrate 102 having a first dopant concentration, a bottom epitaxial semiconductor layer 103 having a second dopant concentration greater than the first dopant concentration, and a top epitaxial semiconductor layer 106 having a third dopant concentration less than the second dopant concentration are sequentially stacked in the stated order in a vertical direction (a Z direction).

The bottom epitaxial semiconductor layer 103 may be integrally connected to the semiconductor substrate 102, and the top epitaxial semiconductor layer 106 may be integrally connected to the bottom epitaxial semiconductor layer 103. The semiconductor substrate 102 may have a frontside surface 102F and a backside surface 102B. A process of forming the base substrate 110 may include a process of forming the bottom epitaxial semiconductor layer 103 by epitaxially growing a semiconductor layer, which is doped at the second dopant concentration, on the frontside surface 102F of the semiconductor substrate 102, and a process of forming the top epitaxial semiconductor layer 106 by epitaxially growing a semiconductor layer, which is doped at the third dopant concentration, on a frontside surface 103F of the bottom epitaxial semiconductor layer 103.

The base substrate 110 may include only the semiconductor substrate 102, the bottom epitaxial semiconductor layer 103, and the top epitaxial semiconductor layer 106. In the base substrate 110, each of the semiconductor substrate 102, the bottom epitaxial semiconductor layer 103, and the top epitaxial semiconductor layer 106 may include silicon (Si) doped with a p-type or n-type dopant. The base substrate 110 may not include germanium (Ge). For example, the base substrate 110 may not include a Ge layer and a SiGe layer. Each of the semiconductor substrate 102, the bottom epitaxial semiconductor layer 103, and the top epitaxial semiconductor layer 106 in the base substrate 110 may include silicon (Si), thereby removing the possibility of crystal defects due to lattice mismatch, which may occur when a Si layer is present together with another semiconductor material layer including germanium (Ge), for example, a SiGe layer or a Ge layer, in the base substrate 110.

In the base substrate 110, the semiconductor substrate 102 may include a Si substrate having a first dopant concentration selected from a range of about 1×10¹⁴ atoms/cm³ to about 1×10¹⁷ atoms/cm³ (e.g., about 1×10¹⁴ atoms/cm³ to about 5×10¹⁵ atoms/cm³). The bottom epitaxial semiconductor layer 103 may include a Si layer having a second dopant concentration that is greater than the first dopant concentration and selected from a range of about 1×10¹⁸ atoms/cm³ to about 1×10²¹ atoms/cm³ (e.g., about 1×10¹⁸ atoms/cm³ to about 1×10²⁰ atoms/cm³). Herein, the bottom epitaxial semiconductor layer 103 may also be referred to as a bottom epitaxial Si layer. The top epitaxial semiconductor layer 106 may include a Si layer having a third dopant concentration that is less than the second dopant concentration and selected from a range of about 1×10¹⁴ atoms/cm³ to about 1×10¹⁷ atoms/cm³ (e.g., about 1×10¹⁴ atoms/cm³ to about 5×10¹⁵ atoms/cm³). Herein, the top epitaxial semiconductor layer 106 may also be referred to as a top epitaxial Si layer.

In some example embodiments, in the base substrate 110, the first dopant concentration of the semiconductor substrate 102 may be equal or similar to the third dopant concentration of the top epitaxial semiconductor layer 106. In some example embodiments, in the base substrate 110, the first dopant concentration of the semiconductor substrate 102 may be different from the third dopant concentration of the top epitaxial semiconductor layer 106. For example, the first dopant concentration may be less or greater than the third dopant concentration.

In some example embodiments, in the base substrate 110, each of the semiconductor substrate 102, the bottom epitaxial semiconductor layer 103, and the top epitaxial semiconductor layer 106 may include silicon (Si) doped with a p-type dopant. The p-type dopant may include boron (B), aluminum (Al), gallium (Ga), indium (In), or a combination thereof. For example, the p-type dopant may include boron (B).

In some example embodiments, in the base substrate 110, each of the semiconductor substrate 102, the bottom epitaxial semiconductor layer 103, and the top epitaxial semiconductor layer 106 may include silicon (Si) doped with an n-type dopant. The n-type dopant may include nitrogen (N), phosphorus (P), arsenic (As), antimony (Sb), or a combination thereof. For example, the n-type dopant may include phosphorus (P).

In some example embodiments, when the semiconductor substrate 102, the bottom epitaxial semiconductor layer 103, and the top epitaxial semiconductor layer 106 in the base substrate 110 each include silicon (Si) doped with a p-type or n-type dopant, at least one of the semiconductor substrate 102, the bottom epitaxial semiconductor layer 103, or the top epitaxial semiconductor layer 106 may further include a neutral dopant, such as carbon (C) or hydrogen (H).

The thickness of each of the semiconductor substrate 102, the bottom epitaxial semiconductor layer 103, and the top epitaxial semiconductor layer 106 in the base substrate 110 may be variously determined as needed. In some example embodiments, in the vertical direction (the Z direction), the thickness of each of the bottom epitaxial semiconductor layer 103 and the top epitaxial semiconductor layer 106 may be selected from a range of about 1/10000 times to about 1/100 times the thickness of the semiconductor substrate 102. For example, in the vertical direction (the Z direction), the thickness of the semiconductor substrate 102 may be selected from a range of about 700 μm to about 800 μm, and the thickness of each of the bottom epitaxial semiconductor layer 103 and the top epitaxial semiconductor layer 106 may be selected from a range of about 0.5 μm to about 3.0 μm, but the inventive concepts are not limited thereto. As such, because the bottom epitaxial semiconductor layer 103 having a dopant concentration, which is greater than a dopant concentration of each of the semiconductor substrate 102 and the top epitaxial semiconductor layer 106, is formed with a relatively small thickness, the volume occupied by the bottom epitaxial semiconductor layer 103 having a relatively high dopant concentration in the base substrate 110 may be relatively small. Therefore, when the top epitaxial semiconductor layer 106 is grown on the frontside surface 103F of the bottom epitaxial semiconductor layer 103, issues due to an auto-doping phenomenon by which dopants in the bottom epitaxial semiconductor layer 103 unintentionally or undesirably diffuse into the top epitaxial semiconductor layer 106 (e.g., an issue of deterioration in the uniformity of a dopant concentration depending on positions in the top epitaxial semiconductor layer 106, or an issue of the occurrence of a difference in dopant concentration between a central portion and an edge portion of the top epitaxial semiconductor layer 106 in a cross-section parallel to a frontside surface 106F of the top epitaxial semiconductor layer 106) may be reduced or prevented.

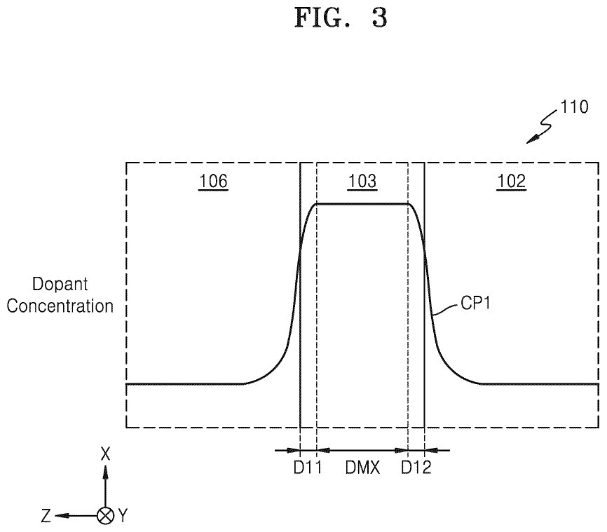

FIG. 3 is a diagram illustrating an example of a dopant concentration profile CP1 in the base substrate 110.

Referring to FIG. 3, the second dopant concentration in the bottom epitaxial semiconductor layer 103 may have a concentration gradient such that the second dopant concentration has a maximum value in a central portion of the bottom epitaxial semiconductor layer 103 based on a total thickness of the bottom epitaxial semiconductor layer 103 in the vertical direction (the Z direction) and gradually decreases away from the central portion of the bottom epitaxial semiconductor layer 103 to edge portions of the bottom epitaxial semiconductor layer 103 that are adjacent to the semiconductor substrate 102 and the top epitaxial semiconductor layer 106, respectively. In the bottom epitaxial semiconductor layer 103, a thickness DMX of the central portion, in which the second dopant concentration has a maximum value, in the vertical direction (the Z direction) may be greater than respective thicknesses D11 and D12 of the edge portions in the vertical direction (the Z direction).

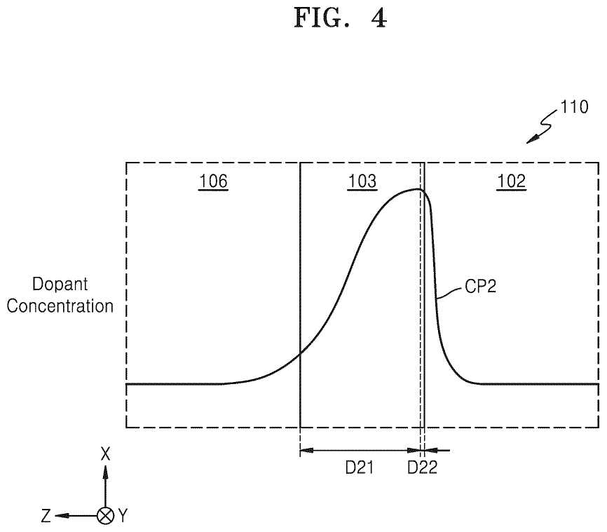

FIG. 4 is a diagram illustrating another example of a dopant concentration profile CP2 in the base substrate 110.

Referring to FIG. 4, the second dopant concentration in the bottom epitaxial semiconductor layer 103 may have a variable concentration gradient in the vertical direction (the Z direction). The second dopant concentration may have a maximum value in an edge portion, which is close to the semiconductor substrate 102 in the vertical direction (the Z direction), of the bottom epitaxial semiconductor layer 103, and the second dopant concentration may gradually decrease toward the top epitaxial semiconductor layer 106 in the vertical direction (the Z direction) from the edge portion, which is close to the semiconductor substrate 102, of the bottom epitaxial semiconductor layer 103. In the bottom epitaxial semiconductor layer 103, a first distance D21 from a portion having the greatest value of the second dopant concentration to the top epitaxial semiconductor layer 106 may be greater in the vertical direction (the Z direction) than a second distance D22 from the portion having the greatest value of the second dopant concentration to the semiconductor substrate 102.

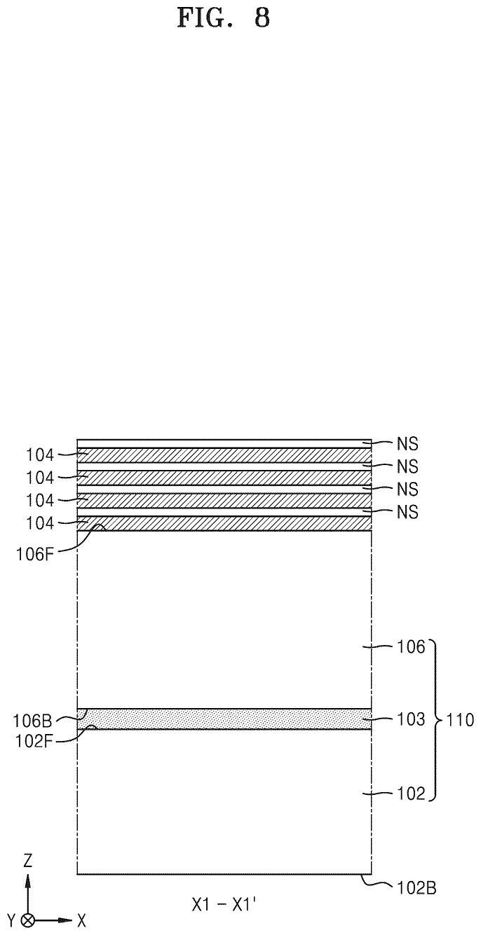

Referring to FIGS. 1 and 2B, in process P14, a front-end-of-line (FEOL) structure FS may be formed on the frontside surface 106F of the top epitaxial semiconductor layer 106 of the base substrate 110. A specific example of a process of forming the FEOL structure FS is described below with reference to FIGS. 8 to 14.

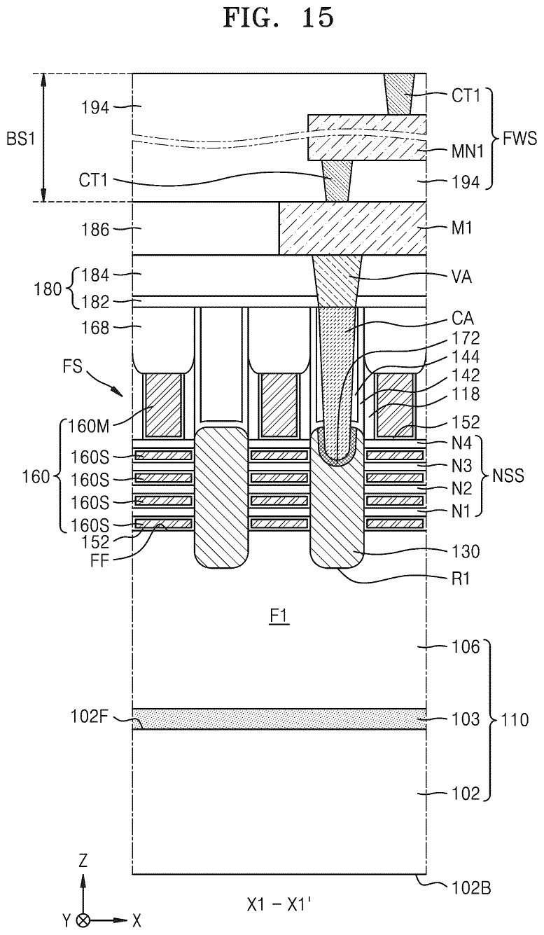

Referring to FIGS. 1 and 2C, in process P16, a first back-end-of-line (BEOL) structure BS1 may be formed on the FEOL structure FS and apart from the base substrate 110 in the vertical direction (the Z direction) with the FEOL structure FS therebetween. A specific example of a process of forming the first BEOL structure BS1 is described below with reference to FIG. 15.

Referring to FIGS. 1 and 2D, in process P18, a sustain wafer SW may be bonded onto the first BEOL structure BS1. Next, the semiconductor substrate 102 may be located (e.g., flipped) to face upward in the vertical direction (the Z direction).

In some example embodiments, the sustain wafer SW may include a Si substrate. In some example embodiments, to bond the sustain wafer SW onto the first BEOL structure BS1, the first BEOL structure BS1 may be aligned to face the sustain wafer SW, and then, the first BEOL structure BS1 and the sustain wafer SW may be bonded to each other.

In some example embodiments, to bond the first BEOL structure BS1 and the sustain wafer SW to each other, a bonding target surface of the first BEOL structure BS1 and a bonding target surface of the sustain wafer SW may each be plasma-cleaned first, followed by pressing the sustain wafer SW toward the first BEOL structure BS1 for the bonding target surface of the sustain wafer SW to contact the first BEOL structure BS1 and perform bonding, and then, an annealing process may be performed.

To plasma-clean the bonding target surface of the first BEOL structure BS1 and the bonding target surface of the sustain wafer SW, plasma and deionized water may be supplied first to the bonding target surface of the first BEOL structure BS1 and the bonding target surface of the sustain wafer SW in a surface treatment chamber. A process gas for forming the plasma may include nitrogen, oxygen, argon, helium, or a combination thereof. The deionized water and the plasma may be simultaneously supplied into the surface treatment chamber or may be sequentially or alternately supplied into the surface treatment chamber. The plasma may function to remove contaminants from the bonding target surface of the first BEOL structure BS1 and the bonding target surface of the sustain wafer SW, and the deionized water may function as a medium of a chemical bond. More specifically, the plasma may break a Si—O bond in a silicon oxide film, which is exposed at the bonding target surface of each of the first BEOL structure BS1 and the sustain wafer SW in a vacuum state, and expose a —Si group at the bonding target surface. The deionized water may cause a —OH group to be formed at the bonding target surface by supplying water (H₂O) to the bonding target surface. Therefore, the —Si group present at the bonding target surface may be maintained to be bonded to the —OH group.

The first BEOL structure BS1 and the sustain wafer SW, which have undergone plasma cleaning as described above, may be dried, thereby removing excess water present at the bonding target surface of each of the first BEOL structure BS1 and the sustain wafer SW.

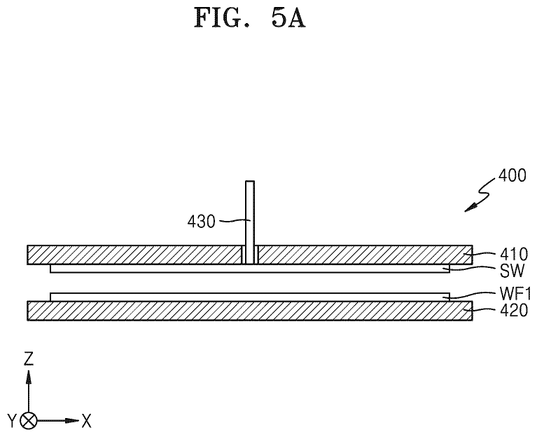

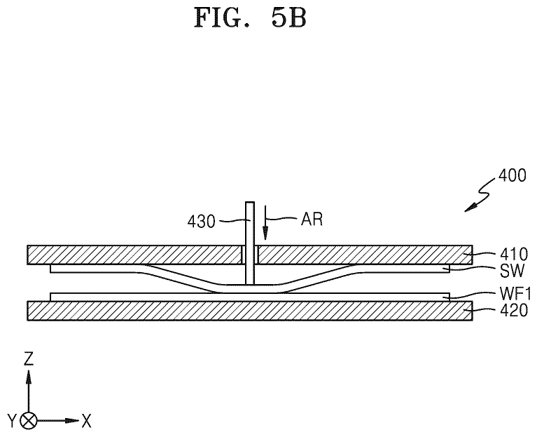

FIGS. 5A and 5B are cross-sectional views respectively illustrating a sequence of processes of an example of a method of bonding the first BEOL structure BS1 and the sustain wafer SW, which have undergone plasma cleaning as described above, to each other according to process P18 of FIG. 1.

Referring to FIG. 5A, the sustain wafer SW may be sucked (e.g., adsorbed) onto a lower surface of an upper chuck 410, which is included in a bonding apparatus 400, in a bonding chamber maintained in a vacuum state, and a process structure WF1 may be sucked (e.g., adsorbed) onto an upper surface of a lower chuck 420. The process structure WF1 is a structure in which the FEOL structure FS and the first BEOL structure BS1 are sequentially formed in the stated order on the base substrate 110, as shown in FIG. 2C. The process structure WF1 may be sucked (e.g., adsorbed) onto the upper surface of a lower chuck 420 such that the base substrate 110 faces the lower chuck 420 and the first BEOL structure BS1 faces the sustain wafer SW.

Referring to FIG. 5B, in the resulting product of FIG. 5A, a central portion of the sustain wafer SW may be pushed down in a direction of an arrow AR by using a push pin 430 of the bonding apparatus 400, thereby bringing the central portion of the sustain wafer SW into contact with a central portion of the process structure WF1. As a result, the central portion of the sustain wafer SW and the central portion of the process structure WF1 may be bonded to each other by intermolecular force between respective surfaces, which contact each other, of the central portion of the sustain wafer SW and the central portion of the process structure WF1.

After bonding between the central portion of the sustain wafer SW and the central portion of the process structure WF1 begins, as bonding waves between the sustain wafer SW and the process structure WF1 propagate outward between the bonding target surfaces in a radial direction from the central portion set forth above, the bonding target surface of the sustain wafer SW may be bonded to the bonding target surface of the first BEOL structure BS1 of the process structure WF1. Here, a Si—OH group present at the bonding target surface of the sustain wafer SW may be bonded to a Si—OH group present at the bonding target surface of the first BEOL structure BS1, and as van der Waals bonding occurs between —OH groups present at the bonding target surfaces of the sustain wafer SW and the first BEOL structure BS1, respectively, water (H₂O) may be separated from between the respective bonding target surfaces of the sustain wafer SW and the first BEOL structure BS1. As a result, the bonding target surface of the sustain wafer SW and the bonding target surface of the first BEOL structure BS1 may be bonded to each other by a Si—O—Si bond. After the bonding process is finished, an annealing process may be performed in a relatively high-temperature atmosphere, and here, water (H₂O) separated from between the respective bonding target surfaces of the sustain wafer SW and the first BEOL structure BS1 may be removed.

Referring to FIGS. 1 and 2E, in process P20, in the resulting product of FIG. 2D in which the first BEOL structure BS1 is bonded to the sustain wafer SW, the semiconductor substrate 102 may be removed to expose the bottom epitaxial semiconductor layer 103 of the bonded base substrate 110.

To remove the semiconductor substrate 102, a mechanical grinding process and a chemical mechanical polishing (CMP) process may be sequentially performed in the stated order. While the CMP process is being performed to remove the semiconductor substrate 102, a portion of the bottom epitaxial semiconductor layer 103 may be consumed by the CMP process. As a result, in the resulting product remaining after the removal process of the semiconductor substrate 102, a vertical-direction (Z-direction) thickness of the bottom epitaxial semiconductor layer 103 remaining on a backside surface 106B of the top epitaxial semiconductor layer 106 may be less than a vertical-direction (Z-direction) thickness of the bottom epitaxial semiconductor layer 103 (indicated by a dashed line in FIG. 2E) before the semiconductor substrate 102 is removed.

After the semiconductor substrate 102 is removed, a dopant concentration in the bottom epitaxial semiconductor layer 103 remaining on the backside surface 106B of the top epitaxial semiconductor layer 106 may be greater than a dopant concentration in the top epitaxial semiconductor layer 106. In some example embodiments, when the bottom epitaxial semiconductor layer 103 has the dopant concentration profile CP2 shown in FIG. 4, the bottom epitaxial semiconductor layer 103 remaining on the backside surface 106B of the top epitaxial semiconductor layer 106 may have a dopant concentration gradually increasing away from the top epitaxial semiconductor layer 106 in the vertical direction (the Z direction).

In process P22 of FIG. 1, a backside process, which includes a first process of removing the bottom epitaxial semiconductor layer 103 by wet etching to expose the backside surface 106B of the top epitaxial semiconductor layer 106 and a second process of patterning the top epitaxial semiconductor layer 106, may be performed, thereby forming a second BEOL structure BS2 (see FIG. 2H) to be apart from the first BEOL structure BS1 in the vertical direction (the Z direction) with the FEOL structure FS therebetween.

The first process of removing the bottom epitaxial semiconductor layer 103 by wet etching may be performed by using the difference in dopant concentration between the top epitaxial semiconductor layer 106 having a relatively low dopant concentration and the bottom epitaxial semiconductor layer 103 having a relatively high dopant concentration. The second process of patterning the top epitaxial semiconductor layer 106 may include a process of removing at least a portion of the top epitaxial semiconductor layer 106 by etching.

In some example embodiments, to perform process P22 of FIG. 1, processes described below with reference to FIGS. 2F, 2G, and 2H may be performed.

Referring to FIG. 2F, the bottom epitaxial semiconductor layer 103 may be removed, by wet etching, from the resulting product in which the bottom epitaxial semiconductor layer 103 remaining after the semiconductor substrate 102 is removed as shown in FIG. 2E according to process P20 of FIG. 1 is exposed, thereby exposing the backside surface 106B of the top epitaxial semiconductor layer 106.

A process of removing the bottom epitaxial semiconductor layer 103 by wet etching may be performed by using the difference in dopant concentration between the top epitaxial semiconductor layer 106 having a relatively low dopant concentration and the bottom epitaxial semiconductor layer 103 having a relatively high dopant concentration. In some example embodiments, to remove the bottom epitaxial semiconductor layer 103 by wet etching, an etching solution including a mixture of an acidic solution, an alkaline solution, and deionized water may be used. For example, the etching solution may include, but is not limited to, an etching solution including about 1 vol % of hydrofluoric acid (HF), about 3 vol % of nitric acid (HNO₃), about 2 vol % of phosphoric acid (H₃PO₄), about 6 vol % of acetic acid (CH₃COOH), and about 88 vol % of deionized water.

Because the dopant concentration in the bottom epitaxial semiconductor layer 103 is greater than the dopant concentration in the top epitaxial semiconductor layer 106, when the bottom epitaxial semiconductor layer 103 is removed by wet etching using the etching solution set forth above, the bottom epitaxial semiconductor layer 103 may be removed with relatively high etch selectivity with respect to the top epitaxial semiconductor layer 106. Therefore, in the resulting product obtained by removing the bottom epitaxial semiconductor layer 103 by wet etching, the bottom epitaxial semiconductor layer 103 may be smoothly removed without the unintentionally or undesirably remaining bottom epitaxial semiconductor layer 103 or the unintended or undesired consumption of a portion of the top epitaxial semiconductor layer 106. As a result, after the bottom epitaxial semiconductor layer 103 is removed, the top epitaxial semiconductor layer 106 may remain in the resulting product while having a relatively constant thickness (e.g., relatively uniform flatness with thickness deviation below a certain value) depending on positions.

In some example embodiments, when the process of removing the semiconductor substrate 102 is performed according to process P20 of FIG. 1, a portion of the bottom epitaxial semiconductor layer 103 may be consumed during the process of removing a portion, which is adjacent to the bottom epitaxial semiconductor layer 103, of the semiconductor substrate 102 by a CMP process. Here, a consumption amount of the bottom epitaxial semiconductor layer 103 may be non-uniform depending on positions in the bottom epitaxial semiconductor layer 103, and thus, the thickness of the bottom epitaxial semiconductor layer 103, which remains on the backside surface 106B of the top epitaxial semiconductor layer 106 after the semiconductor substrate 102 is removed, may not be constant (e.g., may not have relatively uniform flatness with thickness deviation below a certain value) depending on the positions. Here, when the bottom epitaxial semiconductor layer 103 has the dopant concentration profile CP2 shown in FIG. 4, in the bottom epitaxial semiconductor layer 103 remaining on the backside surface 106B of the top epitaxial semiconductor layer 106 after the semiconductor substrate 102 is removed, the dopant concentration at an exposed surface of a portion at a relatively high height is greater than the dopant concentration at an exposed surface of a portion having a relatively low height. Therefore, when the bottom epitaxial semiconductor layer 103 remaining on the backside surface 106B of the top epitaxial semiconductor layer 106 is removed by wet etching according to process P20 of FIG. 1, an etch rate of the portion, which has a relatively high height, of the bottom epitaxial semiconductor layer 103 may be greater than an etch rate of the portion, which has a relatively low height, of the bottom epitaxial semiconductor layer 103. As a result, even when the thickness of the bottom epitaxial semiconductor layer 103 remaining on the backside surface 106B of the top epitaxial semiconductor layer 106 is not constant (e.g., relatively non-uniform flatness with thickness deviation above a certain value) depending on positions in the bottom epitaxial semiconductor layer 103, the bottom epitaxial semiconductor layer 103 may be smoothly removed at all positions in the bottom epitaxial semiconductor layer 103 without an issue in which the bottom epitaxial semiconductor layer 103 unintentionally and/or locally remains while the wet etching process set forth above is being performed.

Referring to FIG. 2G, in the resulting product described with reference to FIG. 2F, a portion of the top epitaxial semiconductor layer 106 may be etched from the backside surface 106B of the top epitaxial semiconductor layer 106, thereby forming a plurality of holes 106H in the top epitaxial semiconductor layer 106 to expose portions of the FEOL structure FS.

Referring to FIG. 2H, in the resulting product described with reference to FIG. 2G, the second BEOL structure BS2, which includes a contact structure CTS filling each of the plurality of holes 106H in the top epitaxial semiconductor layer 106, may be formed.

According to the method, described with reference to FIGS. 2A to 2H, of manufacturing an integrated circuit device, after the first BEOL structure BS1 is formed as described with reference to FIG. 2C, before the second BEOL structure BS2 is formed as described with reference to FIG. 2H, the semiconductor substrate 102 is removed to perform a thinning process for reducing the thickness of the base substrate 110 as described with reference to FIG. 2E, followed by removing the bottom epitaxial semiconductor layer 103 through wet etching by using the difference in dopant concentration between the top epitaxial semiconductor layer 106 having a relatively low dopant concentration and the bottom epitaxial semiconductor layer 103 having a relatively high dopant concentration as described with reference to FIG. 2F, thereby exposing the backside surface 106B of the top epitaxial semiconductor layer 106. Therefore, the top epitaxial semiconductor layer 106 may have the backside surface 106B having improved flatness without a difference in surface roughness (e.g., relatively uniform flatness with thickness deviation below a certain value) depending on positions in the top epitaxial semiconductor layer 106. Therefore, in a manufacturing process of an integrated circuit device having a backside power delivery network (BSPDN) structure, when subsequent processes to a thinning process are performed by using the top epitaxial semiconductor layer 106 remaining in the resulting product having undergone the thinning process for reducing the thickness of the base substrate 110, the backside surface 106B of the top epitaxial semiconductor layer 106 may provide relatively uniform flatness on the entire surface thereof without a thickness deviation (e.g., with a thickness deviation below a certain value) depending on positions in the top epitaxial semiconductor layer 106 remaining in the resulting product, thereby improving the stability in the manufacturing process of an integrated circuit device and/or improving the reliability of the integrated circuit device obtained as a result.

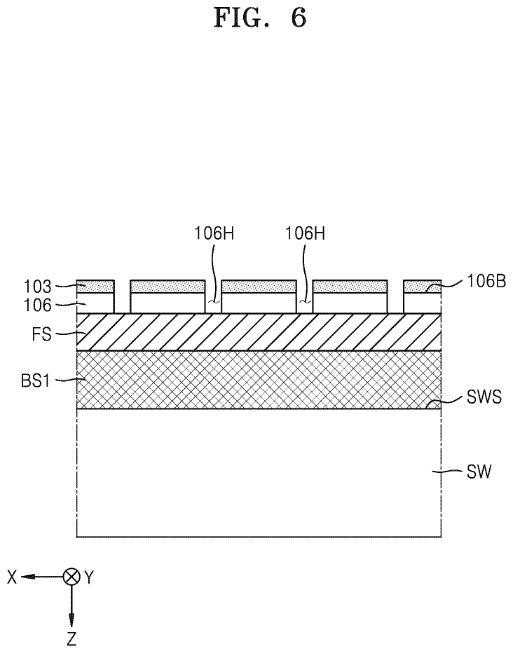

FIG. 6 is a cross-sectional view illustrating a method of manufacturing an integrated circuit device, according to an example embodiment. As another example of performing process P22 of FIG. 1, processes described below with reference to FIG. 6 may be performed.

Referring to FIG. 6, as in the resulting product described with reference to FIG. 2E, while the backside surface 106B of the top epitaxial semiconductor layer 106 is covered by the bottom epitaxial semiconductor layer 103, a portion of each of the bottom epitaxial semiconductor layer 103 and the top epitaxial semiconductor layer 106 may be etched from an exposed surface of the bottom epitaxial semiconductor layer 103 by using an etch mask including a spin-on-hardmask (SOH) material and the like, thereby forming the plurality of holes 106H in the top epitaxial semiconductor layer 106 to expose portions of the FEOL structure FS. After the plurality of holes 106H are formed in the top epitaxial semiconductor layer 106, the backside surface 106B of the top epitaxial semiconductor layer 106 may remain covered by the remaining portion of the bottom epitaxial semiconductor layer 103.

Next, in a similar manner to that described with reference to FIG. 2F, the backside surface 106B of the top epitaxial semiconductor layer 106 may be exposed by removing the bottom epitaxial semiconductor layer 103 remaining in the resulting product of FIG. 6 by wet etching, and then, in a similar manner to that described with reference to FIG. 2H, the second BEOL structure BS2, which includes a contact structure CTS filling each of the plurality of holes 106H in the top epitaxial semiconductor layer 106, may be formed.

According to the method, described with reference to FIG. 6, of manufacturing an integrated circuit device, similar to the descriptions made with reference to FIGS. 1 and 2A to 2H, after the semiconductor substrate 102 is removed by a thinning process for reducing the thickness of the base substrate 110, the method includes a process of exposing the backside surface 106B of the top epitaxial semiconductor layer 106 by removing the bottom epitaxial semiconductor layer 103 through wet etching by using the difference in dopant concentration between the top epitaxial semiconductor layer 106 having a relatively low dopant concentration and the bottom epitaxial semiconductor layer 103 having a relatively high dopant concentration. For example, in the method, described with reference to FIG. 6, of manufacturing an integrated circuit device, because the bottom epitaxial semiconductor layer 103 is removed by wet etching after the process of forming the plurality of holes 106H in the top epitaxial semiconductor layer 106 is performed, the backside surface 106B of the top epitaxial semiconductor layer 106 may be protected by the bottom epitaxial semiconductor layer 103 while the plurality of holes 106H are being formed in the top epitaxial semiconductor layer 106. Therefore, the possibility of surface damage, which the top epitaxial semiconductor layer 106 may suffer from during the formation of the plurality of holes 106H in the top epitaxial semiconductor layer 106, due to an etching process atmosphere may be reduced or prevented by the bottom epitaxial semiconductor layer 103, and after the plurality of holes 106H are formed in the top epitaxial semiconductor layer 106, because the bottom epitaxial semiconductor layer 103 is removed by wet etching by using the difference in dopant concentration between the top epitaxial semiconductor layer 106 having a relatively low dopant concentration and the bottom epitaxial semiconductor layer 103 having a relatively high dopant concentration, the top epitaxial semiconductor layer 106 may have the backside surface 106B having improved flatness without a difference in surface roughness (e.g., with a thickness deviation below a certain value) depending on positions in the top epitaxial semiconductor layer 106. Therefore, when subsequent processes are performed by using the top epitaxial semiconductor layer 106 including the plurality of holes 106H, the backside surface 106B of the top epitaxial semiconductor layer 106 may provide uniform flatness on the entire surface thereof without a thickness deviation (e.g., with a thickness deviation below a certain value) depending on positions in the top epitaxial semiconductor layer 106 remaining in the resulting product, thereby improving the stability in a manufacturing process of an integrated circuit device and/or improving the reliability of the integrated circuit device obtained as a result.

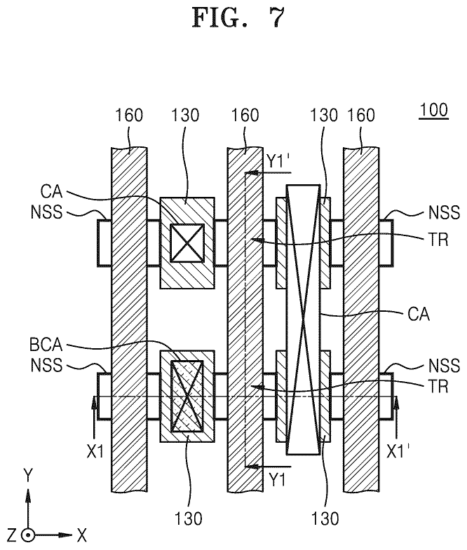

FIG. 7 is an example of a planar layout diagram of the integrated circuit device 100 that may be manufactured by a method of manufacturing an integrated circuit device, according to an example embodiment.

Referring to FIG. 7, the integrated circuit device 100 may include a plurality of nanosheet stacks NSS, a plurality of gate lines 160 respectively surrounding the plurality of nanosheet stacks NSS, and a plurality of source/drain regions 130 arranged one-by-one between two adjacent gate lines 160 from among the plurality of gate lines 160. In the integrated circuit device 100, the plurality of gate lines 160, the plurality of nanosheet stacks NSS, and the plurality of source/drain regions 130 may constitute a plurality of field-effect transistors TR each having a gate-all-around (GAA) structure.

The plurality of nanosheet stacks NSS may be arranged apart from each other in a first horizontal direction (an X direction) and a second horizontal direction (a Y direction), which are orthogonal to each other. The plurality of gate lines 160 may be apart from each other in the first horizontal direction (the X direction) and may extend lengthwise in the second horizontal direction (the Y direction). Frontside source/drain contacts CA may be respectively connected to some source/drain regions 130 selected from the plurality of source/drain regions 130. Backside via contacts BCA may be respectively connected to some other source/drain regions 130 selected from the plurality of source/drain regions 130.

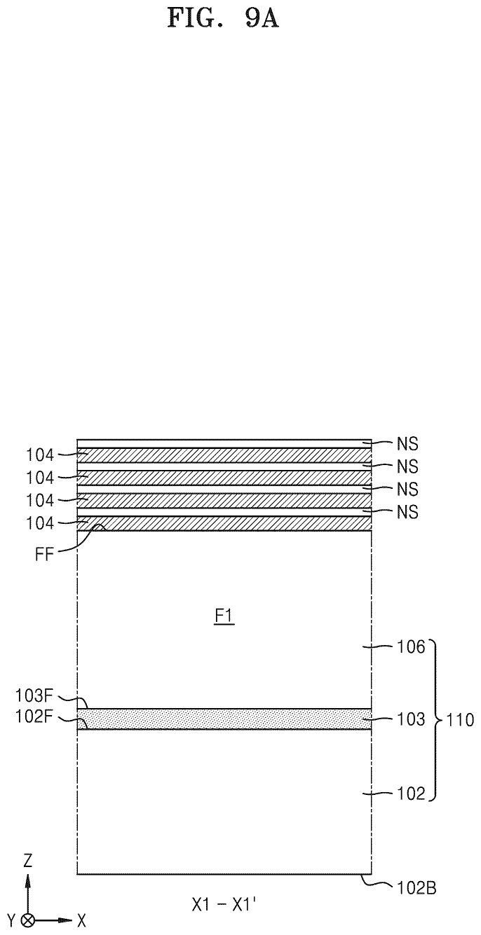

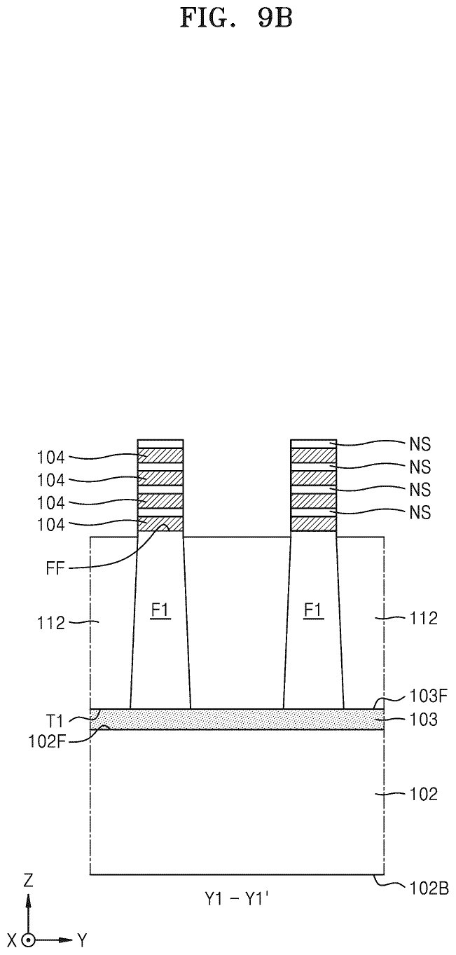

FIGS. 8 to 24 are cross-sectional views illustrating a sequence of processes of a method of manufacturing the integrated circuit device 100 shown in FIG. 7, and in particular, FIGS. 8, 9A, 10A, 11A, 12A, 13A, 14, 15, 16, 17, 18, 19, 20, 21, 22, 23, and 24 are cross-sectional views respectively illustrating cross-sectional structures of a region corresponding to a cross-section taken along a line X1-X1′ of FIG. 7, according to the sequence of processes, and FIGS. 9B, 10B, 11B, 12B, and 13B are cross-sectional views respectively illustrating cross-sectional structures of a region corresponding to a cross-section taken along a line Y1-Y1′ of FIG. 7, according to the sequence of processes. In FIGS. 8 to 24, the same reference numerals as in FIGS. 2A to 2H respectively denote the same members, and here, repeated descriptions thereof are omitted.

Referring to FIG. 8, the base substrate 110 including the semiconductor substrate 102, the bottom epitaxial semiconductor layer 103, and the top epitaxial semiconductor layer 106 is formed by the method described with reference to process P12 of FIG. 1 and to FIG. 2A, and then, a stack structure, in which a plurality of sacrificial semiconductor layers 104 and a plurality of nanosheet semiconductor layers NS are alternately stacked one-by-one, may be formed on the frontside surface 106F of the top epitaxial semiconductor layer 106.

In the stack structure, each of the plurality of sacrificial semiconductor layers 104 and each of the plurality of nanosheet semiconductor layers NS may respectively include semiconductor materials having different etch selectivities. In some example embodiments, each of the plurality of nanosheet semiconductor layers NS may include a Si layer, and each of the plurality of sacrificial semiconductor layers 104 may include a SiGe layer. The SiGe layer constituting each of the plurality of sacrificial semiconductor layers 104 may have a constant Ge content selected from a range of about 5 at % to about 50 at % (e.g., about 10 at % to about 40 at %). In some example embodiments, each of the plurality of sacrificial semiconductor layers 104 may include a SiGe layer, and the respective Ge contents in the plurality of sacrificial semiconductor layers 104 may be equal to each other.

Referring to FIGS. 9A and 9B, in the resulting product of FIG. 8, each of the plurality of sacrificial semiconductor layers 104, the plurality of nanosheet semiconductor layers NS, and the top epitaxial semiconductor layer 106 may be partially etched, thereby forming a plurality of fin-type active regions F1 including remaining portions of the top epitaxial semiconductor layer 106, respectively. A plurality of trench regions T1 may be defined over the semiconductor substrate 102 by the plurality of fin-type active regions F1. The bottom epitaxial semiconductor layer 103 may be exposed at a lower surface of each of the plurality of trench regions T1. A portion of each of the plurality of sacrificial semiconductor layers 104 and the plurality of nanosheet semiconductor layers NS may remain on or over a fin top surface FF of each of the plurality of fin-type active regions F1.

Next, a device isolation film 112 may be formed to fill the plurality of trench regions T1. The device isolation film 112 may include portions respectively contacting sidewalls of the plurality of fin-type active regions F1 and portions contacting the frontside surface 103F of the bottom epitaxial semiconductor layer 103. The device isolation film 112 may include an oxide film, a nitride film, or a combination thereof. The plurality of sacrificial semiconductor layers 104 and the plurality of nanosheet semiconductor layers NS, which remain on or over the fin top surface FF of each of the plurality of fin-type active regions F1, may protrude upward from the upper surface of the device isolation film 112.

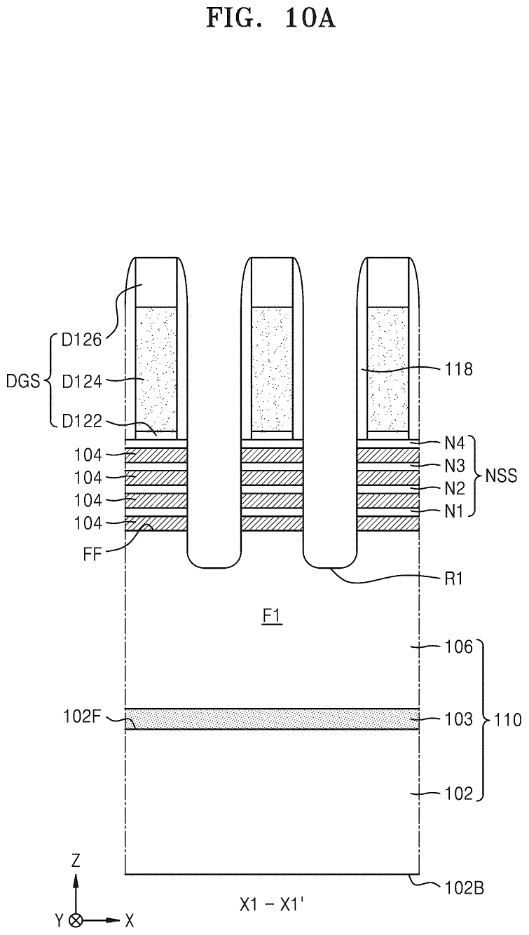

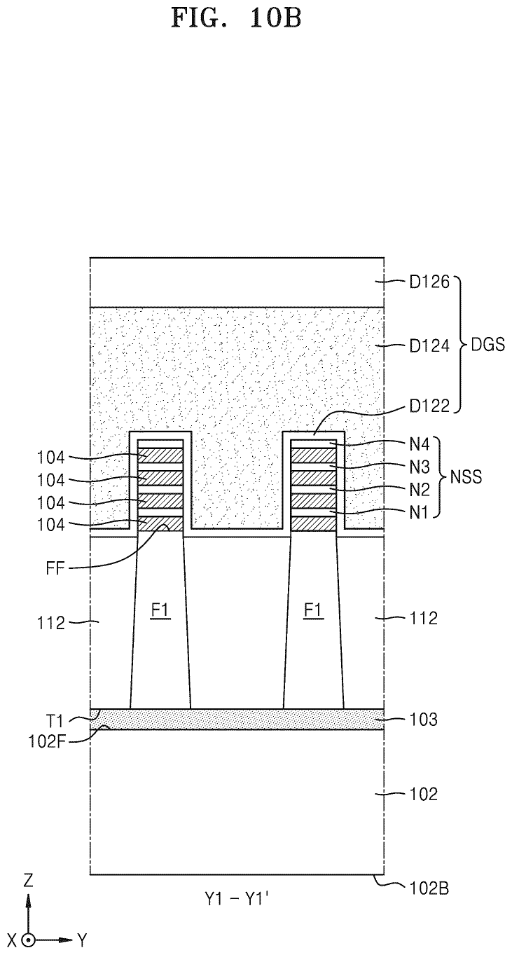

Referring to FIGS. 10A and 10B, a plurality of dummy gate structures DGS may be formed on the resulting product of FIGS. 9A and 9B. Each of the plurality of dummy gate structures DGS may be formed to extend lengthwise in the second horizontal direction (the Y direction). Each of the plurality of dummy gate structures DGS may include a dummy oxide film D122, a dummy gate layer D124, and a capping layer D126, which are stacked in the stated order on the stack structure including the plurality of sacrificial semiconductor layers 104 and the plurality of nanosheet semiconductor layers NS. In some example embodiments, the dummy gate layer D124 may include polysilicon and the capping layer D126 may include a silicon nitride film.

A plurality of insulating spacers 118 may be formed to respectively cover both sidewalls of each of the plurality of dummy gate structures DGS. The plurality of insulating spacers 118 may each include silicon nitride, silicon oxide, SiOC, SiOCN, SiCN, SiBN, SiON, SiBCN, SiOF, SiOCH, or a combination thereof.

A portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as an etch mask, thereby dividing the plurality of nanosheet semiconductor layers NS into the plurality of nanosheet stacks NSS, each of which includes first to fourth nanosheets N1, N2, N3, and N4, and forming a plurality of recesses R1 in an upper portion of the fin-type active region F1. The width of each of the first to fourth nanosheets N1, N2, N3, and N4 in the first horizontal direction (the X direction) may be defined by the plurality of recesses R1. To form the plurality of recesses R1, the etching may be performed by dry etching, wet etching, or a combination thereof.

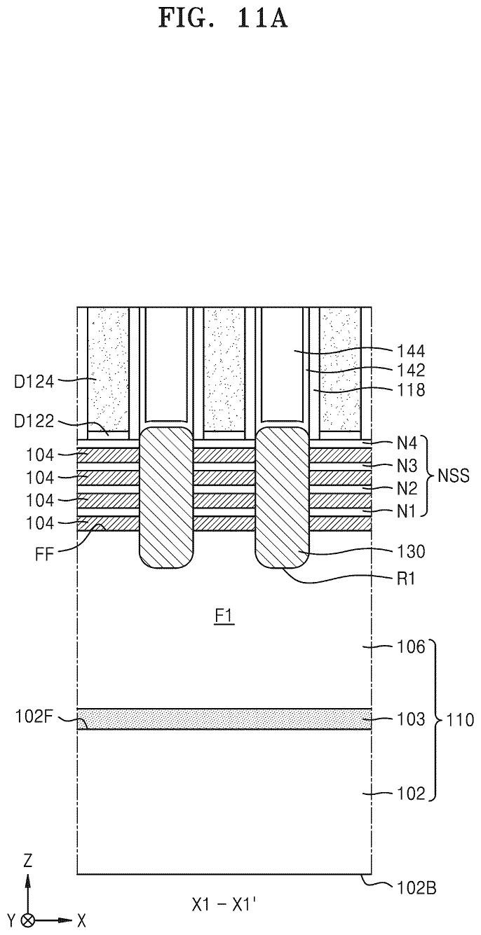

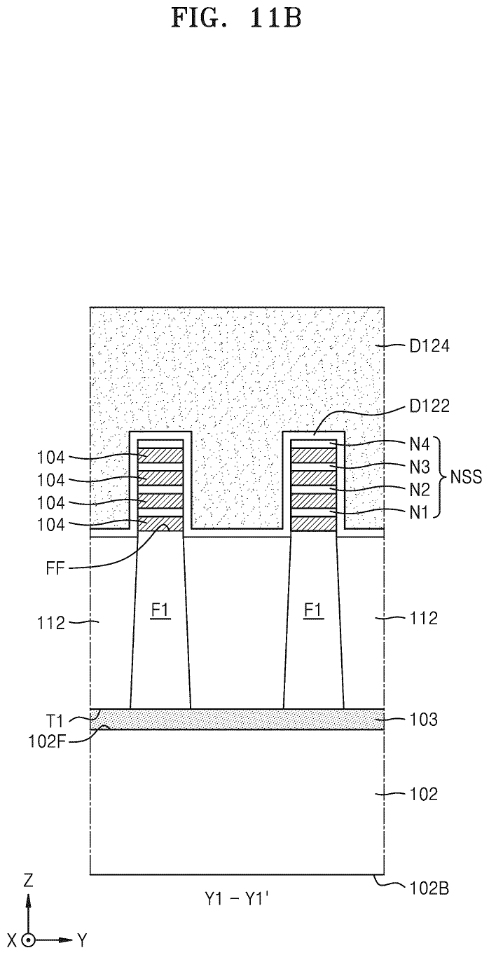

Referring to FIGS. 11A and 11B, the plurality of source/drain regions 130 may be formed by epitaxially growing a semiconductor material on respective surfaces of the fin-type active region F1, the first to fourth nanosheets N1, N2, N3, and N4, and the plurality of sacrificial semiconductor layers 104, which are exposed by each recess R1. Each of the plurality of source/drain regions 130 may include an epitaxially grown semiconductor layer. In some example embodiments, each of the plurality of source/drain regions 130 may include a Si layer, a SiC layer, or a SiGe layer. In some example embodiments, when a source/drain region 130 constitutes an NMOS transistor, the source/drain region 130 may include a SiC layer doped with an n-type dopant. The n-type dopant may be selected from phosphorus (P), arsenic (As), and antimony (Sb). In some example embodiments, when the source/drain region 130 constitutes a PMOS transistor, the source/drain region 130 may include a SiGe layer doped with a p-type dopant. The p-type dopant may be selected from boron (B) and gallium (Ga).

An insulating liner 142 may be formed to cover a resulting product in which the plurality of source/drain regions 130 are formed, and an inter-gate dielectric 144 may be formed on the insulating liner 142. The insulating liner 142 may include silicon nitride, SiCN, SiBN, SiON, SiOCN, SiBCN, or a combination thereof, and the inter-gate dielectric 144 may include a silicon oxide film, but the inventive concepts are not limited thereto.

Next, a portion of each of the insulating liner 142 and the inter-gate dielectric 144 may be etched, thereby exposing upper surfaces of a plurality of capping layers D126 (see FIGS. 10A and 10B). Next, the dummy gate layer D124 may be exposed by removing the plurality of capping layers D126, and the insulating liner 142 and the inter-gate dielectric 144 may be partially removed such that the upper surface of the inter-gate dielectric 144 and the upper surface of the dummy gate layer D124 are at an approximately equal level.

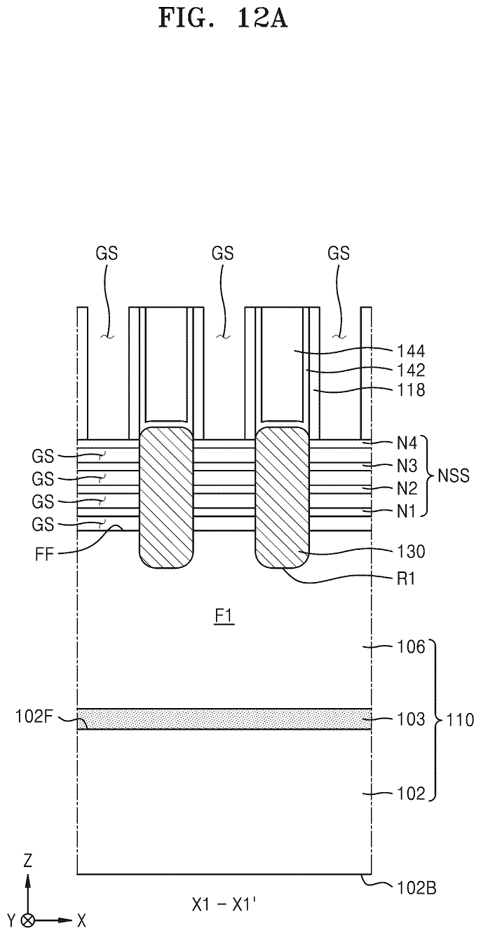

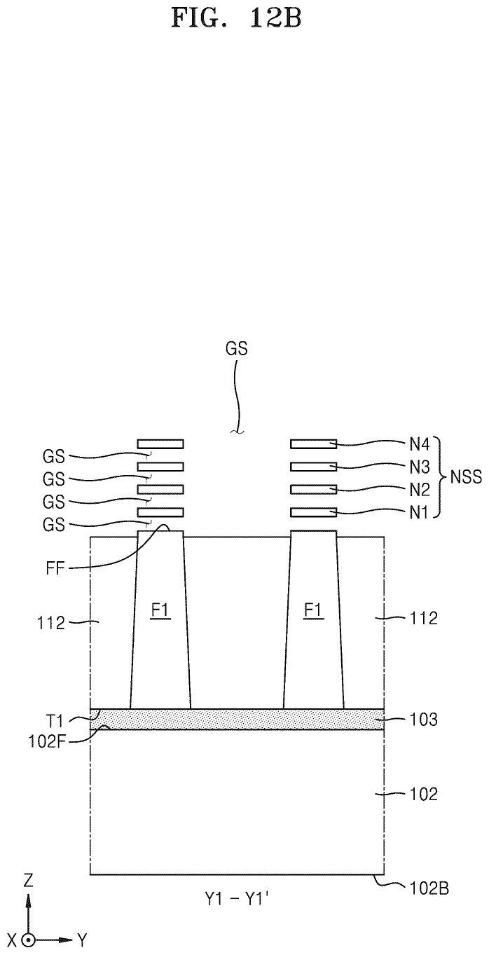

Referring to FIGS. 12A and 12B, the dummy gate layer D124 and the dummy oxide film D122 may be removed from the resulting product of FIGS. 11A and 11B, thereby preparing a gate space GS. Next, the plurality of sacrificial semiconductor layers 104 remaining over the fin-type active region F1 may be selectively removed through the gate space GS, thereby expanding the gate space GS to a space between each of the first to fourth nanosheets N1, N2, N3, and N4 and to a space between the fin top surface FF of the fin-type active region F1 and the first nanosheet N1.

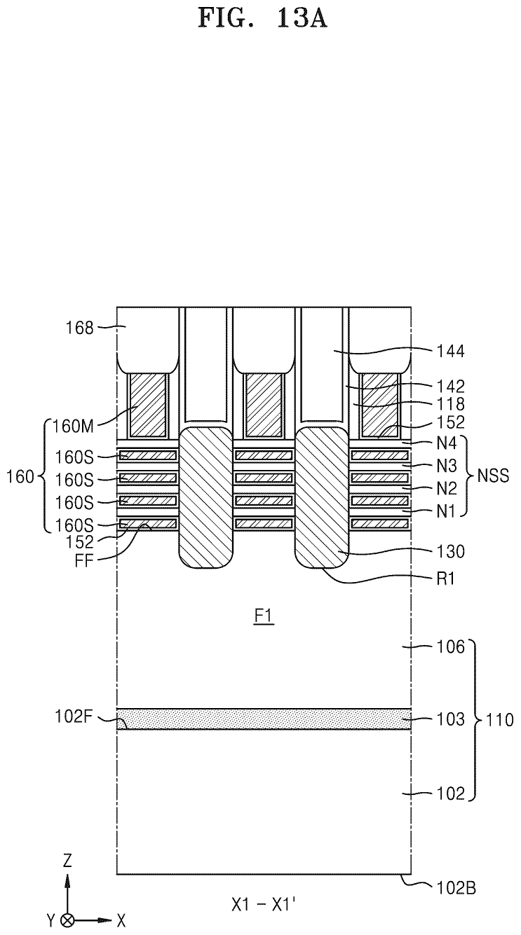

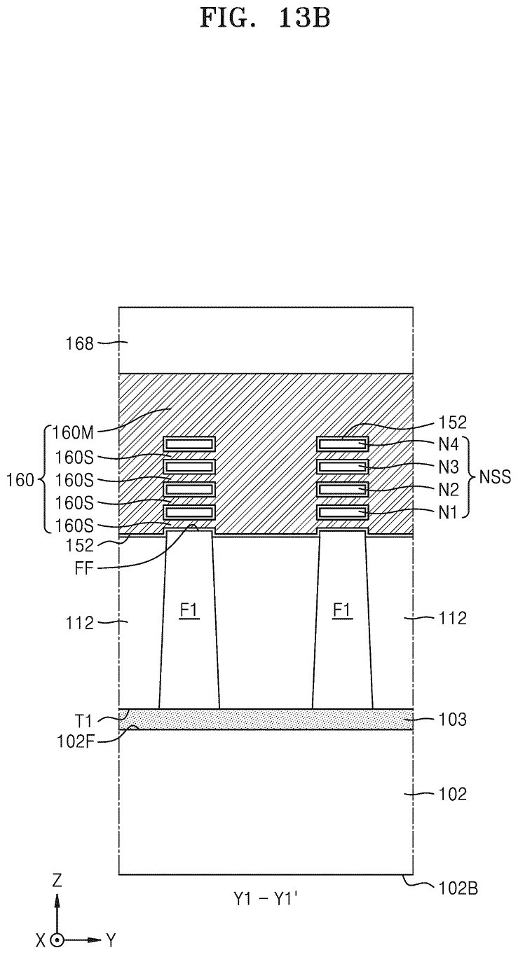

Referring to FIGS. 13A and 13B, in the resulting product of FIGS. 12A and 12B, a gate dielectric film 152 may be formed to cover exposed surfaces of the fin-type active region F1 and the first to fourth nanosheets N1, N2, N3, and N4. The gate dielectric film 152 may include a stack structure of an interface dielectric film and a high-k film. The interface dielectric film may include a low-k material film having a dielectric constant of about 9 or less, for example, a silicon oxide film, a silicon oxynitride film, or a combination thereof. In some example embodiments, the interface dielectric film may be omitted. The high-k film may include a material having a dielectric constant that is greater than that of a silicon oxide film. For example, the high-k film may have a dielectric constant of about 10 to about 25. The high-k film may include, but is not limited to, hafnium oxide.

A plurality of gate lines 160 may each be formed on the gate dielectric film 152 to fill the gate space GS (see FIGS. 12A and 12B). Each of the plurality of gate lines 160 may include metal, metal nitride, metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. However, a material constituting each of the plurality of gate lines 160 is not limited to the examples set forth above.

Each of the gate line 160, the gate dielectric film 152, and the insulating spacer 118 may be partially removed from the upper surface thereof to reduce the height thereof, and a plurality of capping insulating patterns 168 may each be formed to cover the upper surface of each of the gate line 160, the gate dielectric film 152, and the insulating spacer 118. Each of the plurality of capping insulating patterns 168 may include a silicon nitride film.

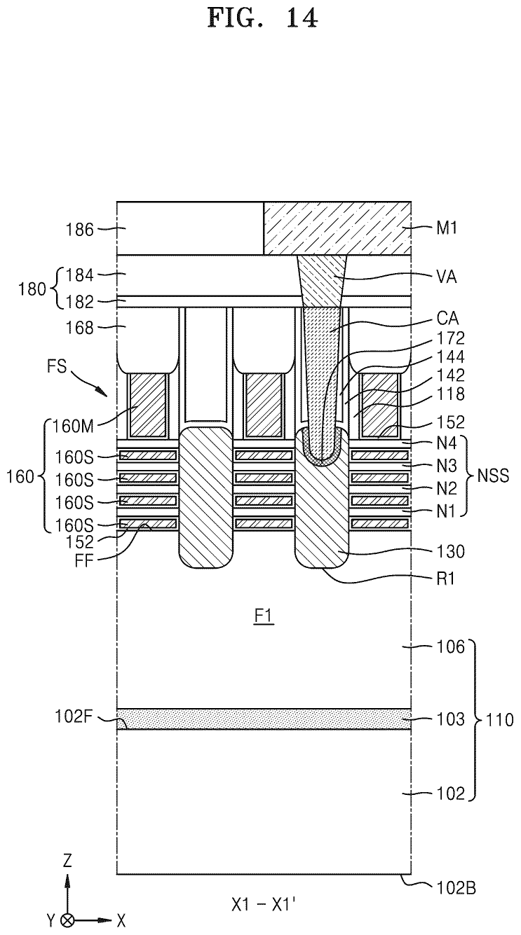

Referring to FIG. 14, in the resulting product of FIGS. 13A and 13B, a source/drain contact hole may be formed between two adjacent gate lines 160 from among the plurality of gate lines 160 to expose the source/drain region 130, followed by forming a frontside metal silicide film 172 on the surface of the source/drain region 130 through the source/drain contact hole, and then, a frontside source/drain contact CA may be formed on the frontside metal silicide film 172 to fill the source/drain contact hole. The frontside metal silicide film 172 may include metal including at least one of Ti, W, Ru, Nb, Mo, Hf, Ni, Co, Pt, Yb, Tb, Dy, Er, or PD. For example, the frontside metal silicide film 172 may include, but is not limited to, titanium silicide. In some example embodiments, the frontside source/drain contact CA may include only a metal plug including a single metal. In some example embodiments, the frontside source/drain contact CA may include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof. The conductive barrier film may include metal or conductive metal nitride. For example, the conductive barrier film may include, but is not limited to, Ti, Ta, W, TiN, TaN, WN, WCN, TiSiN, TaSiN, WSiN, or a combination thereof.

An etch stop film 182 and an upper insulating film 184 may be formed in the stated order to cover the upper surface of each of the frontside source/drain contact CA, the plurality of capping insulating patterns 168, and the inter-gate dielectric 144, thereby forming an upper insulating structure 180. Next, a source/drain via contact VA, which passes through the upper insulating structure 180 in the vertical direction (the Z direction) to be connected to the frontside source/drain contact CA, and a gate contact (not shown), which passes through the upper insulating structure 180 and the capping insulating pattern 168 in the vertical direction (the Z direction) to be connected to the gate line 160, may be formed.

The etch stop film 182 may include silicon carbide (SiC), SiN, SiCN, SiOC, AlN, AlON, AlO, AlOC, or a combination thereof. The upper insulating film 184 may include an oxide film, a nitride film, an ultra-low k (ULK) film having an ultra-low dielectric constant of about 2.2 to about 2.4, or a combination thereof. For example, the upper insulating film 184 may include, but is not limited to, a tetraethylorthosilicate (TEOS) film, a high-density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof. Each of the source/drain via contact VA and the gate contact may include a contact plug including molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof. In some example embodiments, each of the source/drain via contact VA and the gate contact may further include a conductive barrier pattern surrounding the contact plug. The conductive barrier pattern may include metal or metal nitride. For example, the conductive barrier pattern may include, but is not limited to, Ti, Ta, W, TiN, TaN, WN, WCN, TiSiN, TaSiN, WSiN, or a combination thereof.

Next, an interlayer dielectric 186, which covers the upper insulating structure 180, and a plurality of upper wiring layers M1, which pass through the interlayer dielectric 186, may be formed. A constituent material of the interlayer dielectric 186 is the same as or substantially similar to the constituent material of the upper insulating film 184 described above. An upper wiring layer M1 may be connected to the source/drain via contact VA or the gate contact. The upper wiring layer M1 may include, but is not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

Referring to FIG. 15, a first BEOL structure BS1 may be formed on the plurality of upper wiring layers M1 and the interlayer dielectric 186. The first BEOL structure BS1 may include a frontside wiring structure FWS including a wiring layer MN1, a via contact CT1, and an interlayer dielectric 194 covering the wiring layer MN1 and the via contact CT1. A constituent material of each of the wiring layer MN1 and the via contact CT1 is the same as or substantially similar to the constituent material of each of the plurality of upper wiring layers M1 described above. A constituent material of the interlayer dielectric 194 is the same as or substantially similar to the constituent material of the upper insulating film 184.

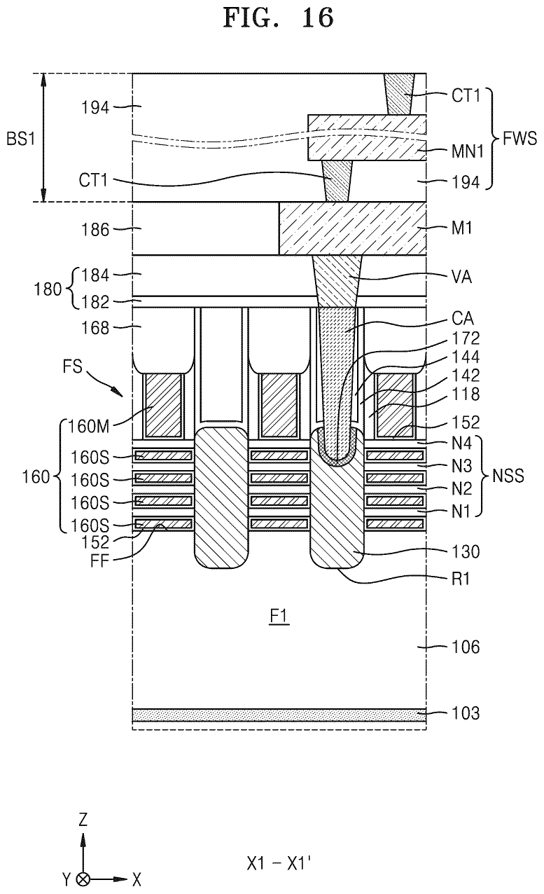

Referring to FIG. 16, the first BEOL structure BS1, which is included in the resulting product having undergone the process described with reference to FIG. 15, may be bonded to a sustain wafer SW (see FIG. 2D). To bond the first BEOL structure BS1 to the sustain wafer SW, a similar method to that described with reference to FIGS. 2D, 5A, and 5B may be performed. In FIGS. 16 to 24, the sustain wafer SW is omitted.

While the first BEOL structure BS1 is bonded to the sustain wafer SW, the semiconductor substrate 102 may be removed to expose the bottom epitaxial semiconductor layer 103 in the same manner as in process P20 of FIG. 1 described with reference to FIG. 2E. As described with reference to FIG. 2E, while a CMP process is being performed to remove the semiconductor substrate 102, a portion of the bottom epitaxial semiconductor layer 103 may be consumed. Therefore, in the resulting product remaining after the removal process of the semiconductor substrate 102 is completed, the vertical-direction (Z-direction) thickness of the bottom epitaxial semiconductor layer 103 remaining on the backside surface 106B of the top epitaxial semiconductor layer 106 may be less than the vertical-direction (Z-direction) thickness of the bottom epitaxial semiconductor layer 103 (indicated by a dashed line in FIG. 16) before the semiconductor substrate 102 is removed.

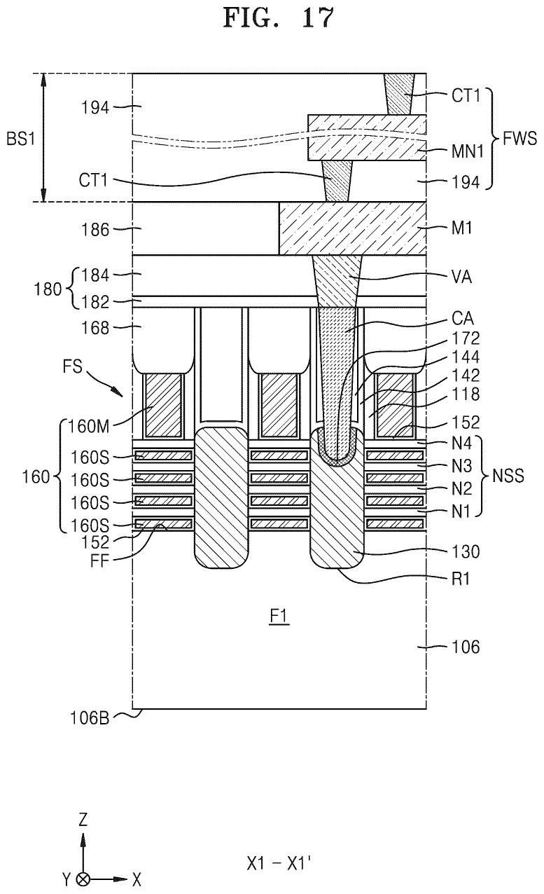

Referring to FIG. 17, the bottom epitaxial semiconductor layer 103 may be removed by wet etching in the same manner as described with reference to FIG. 2F, thereby exposing the backside surface 106B of the fin-type active region F1 that is a portion of the top epitaxial semiconductor layer 106.

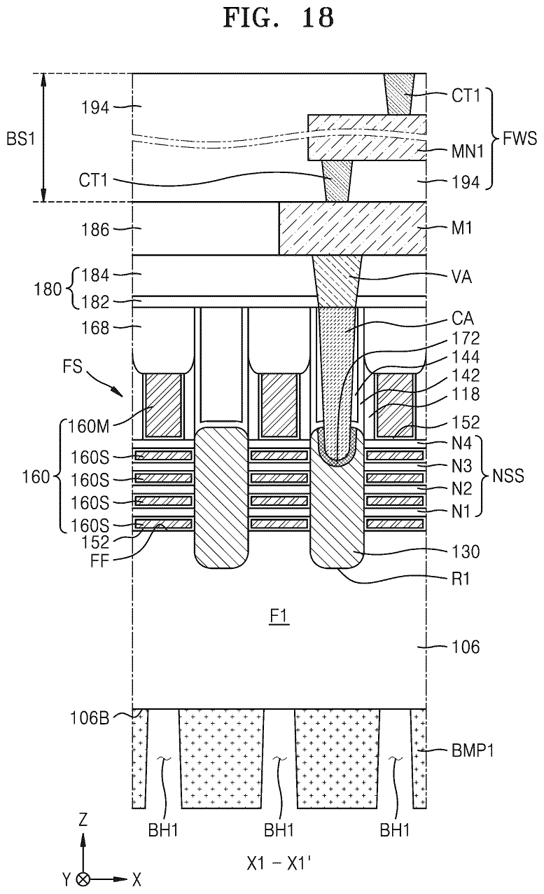

Referring to FIG. 18, in the resulting product of FIG. 17, a first backside mask pattern BMP1 may be formed on the backside surface 106B of the fin-type active region F1 that is a portion of the top epitaxial semiconductor layer 106. The first backside mask pattern BMP1 may have a plurality of line-shaped openings BH1 extending lengthwise in the second horizontal direction (the Y direction). A portion of each of the device isolation film 112 and the plurality of fin-type active regions F1 may be exposed by the plurality of line-shaped openings BH1 formed in the first backside mask pattern BMP1. In some example embodiments, the first backside mask pattern BMP1 may include, but is not limited to, an SOH material.

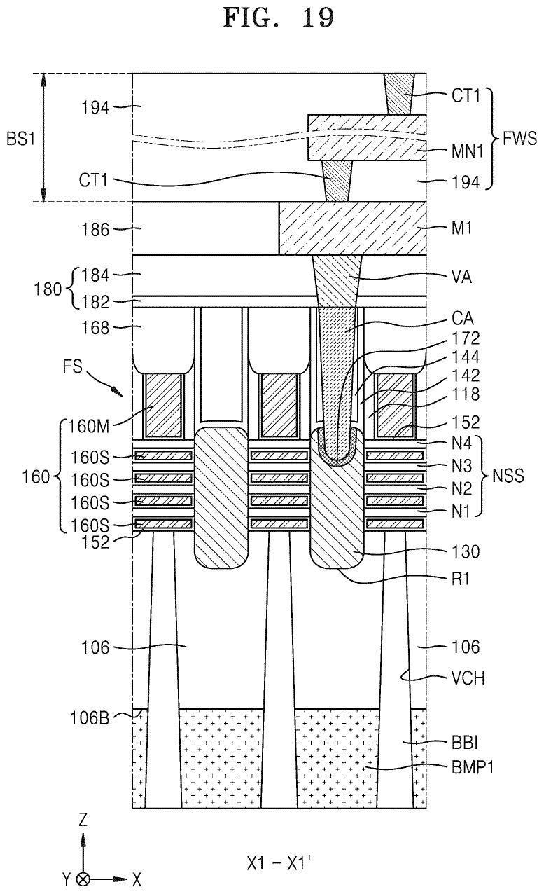

Referring to FIG. 19, in the resulting product of FIG. 18, a plurality of vertical holes VCH may each be formed to expose the gate dielectric film 152 by etching a portion of the fin-type active region F1 by using the first backside mask pattern BMP1 as an etch mask, and a plurality of backside bulk insulating films BBI may be formed to fill the plurality of vertical holes VCH and the plurality of line-shaped openings BH1 (see FIG. 18). In some example embodiments, to form the plurality of backside bulk insulating films BBI, an atomic layer deposition (ALD) process or a CVD process may be used, but the inventive concepts are not limited thereto. After the plurality of backside bulk insulating films BBI are formed, a structure, in which a portion of the top epitaxial semiconductor layer 106 is arranged between each of the plurality of backside bulk insulating films BBI, may be obtained.

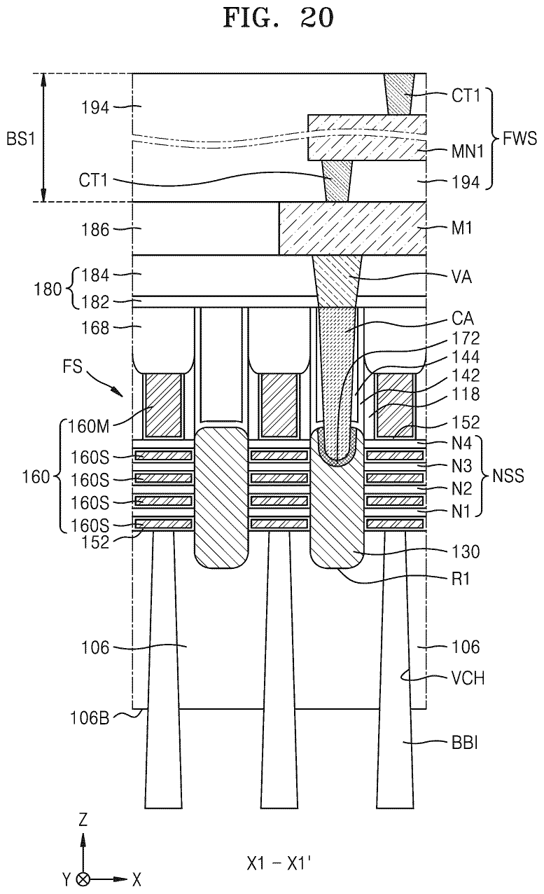

Referring to FIG. 20, the first backside mask pattern BMP1 may be removed from the resulting product of FIG. 19. When the first backside mask pattern BMP1 includes an SOH material, ashing and strip processes may be used to remove the first backside mask pattern BMP1.

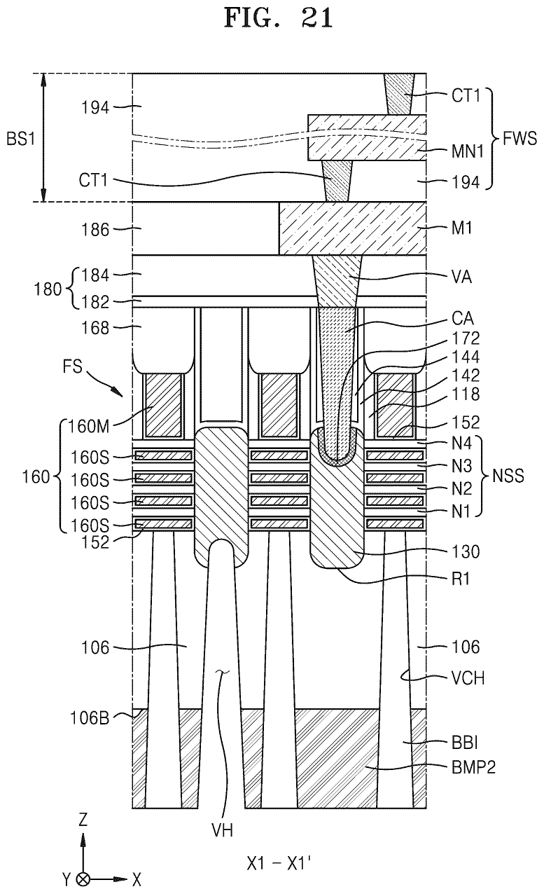

Referring to FIG. 21, a planarized hardmask film may be formed by coating an SOH material on the resulting product of FIG. 20, and a second backside mask pattern BMP2, which has a hole exposing a portion of the top epitaxial semiconductor layer 106, may be formed by patterning the hardmask film. Next, the fin-type active region F1, which is a portion of the top epitaxial semiconductor layer 106, may be partially etched by using the second backside mask pattern BMP2 as an etch mask, thereby forming a via hole VH in the fin-type active region F1 to expose the source/drain region 130. While the via hole VH is being formed, a portion of the source/drain region 130 may be etched, and thus, the via hole VH may extend to the inside of the source/drain region 130.

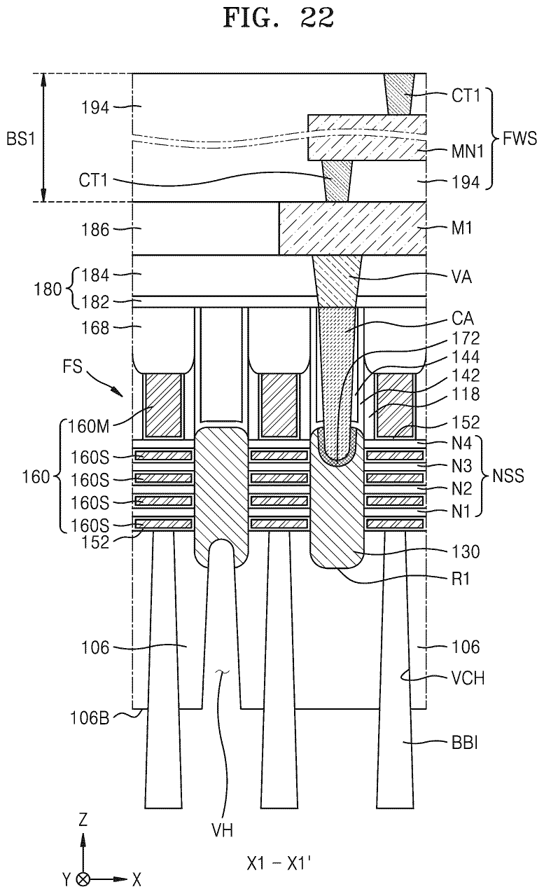

Referring to FIG. 22, the second backside mask pattern BMP2 may be removed from the resulting product of FIG. 21. When the second backside mask pattern BMP2 includes an SOH material, ashing and strip processes may be used to remove the second backside mask pattern BMP2.

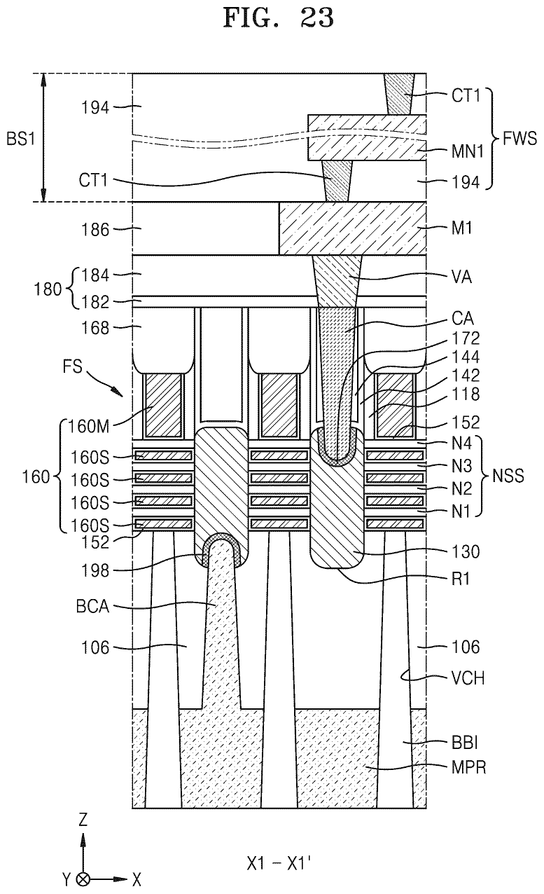

Referring to FIG. 23, in the resulting product of FIG. 22, a backside metal silicide film 198 may be formed on the surface of the source/drain region 130 through the via hole VH. A constituent material of the backside metal silicide film 198 is the same as or substantially similar to the constituent material of the frontside metal silicide film 172 described above. Next, a conductive material may fill the via hole VH and a space between each of the plurality of backside bulk insulating films BBI, thereby forming a backside via contact BCA, which fills the via hole VH, and a backside power rail MPR integrally connected to the backside via contact BCA. The backside via contact BCA may be configured to be connected to the source/drain region 130 via the backside metal silicide film 198. Herein, the backside via contact BCA may be referred to as a contact structure. A constituent material of each of the backside via contact BCA and the backside power rail MPR is the same as or substantially similar to the constituent material of the frontside source/drain contact CA.

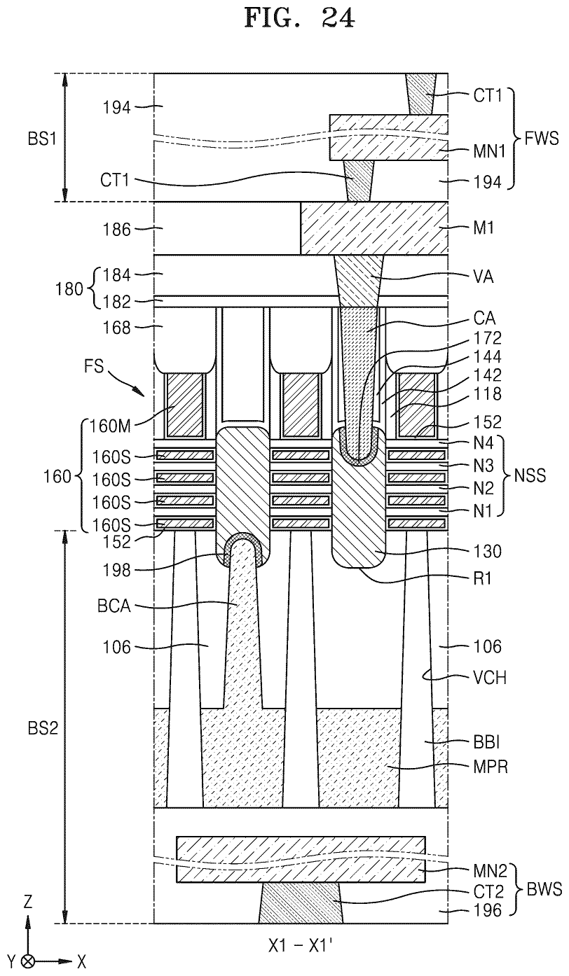

Referring to FIG. 24, a backside wiring structure BWS, which includes a wiring layer MN2, a via contact CT2, and an interlayer dielectric 196 covering the wiring layer MN2 and the via contact CT2, may be formed on the resulting product of FIG. 23, in which the backside via contact BCA and the backside power rail MPR are formed. The backside via contact BCA, the backside power rail MPR, and the backside wiring structure BWS may constitute a second BEOL structure BS2. A constituent material of each of the wiring layer MN2 and the via contact CT2 is the same as or substantially similar to the constituent material of the upper wiring layer M1. A constituent material of the interlayer dielectric 196 is the same as or substantially similar to the constituent material of the upper insulating film 184.

According to the method, described with reference to FIGS. 8 to 24, of manufacturing an integrated circuit device, after the first BEOL structure BS1 is formed as described with reference to FIG. 15, before the second BEOL structure BS2 is formed, the semiconductor substrate 102 may be removed to reduce the thickness of the base substrate 110, followed by removing the bottom epitaxial semiconductor layer 103, which has a relatively high dopant concentration, by wet etching by using the difference in dopant concentration as described with reference to FIG. 16, thereby exposing the backside surface 106B of the fin-type active region F1 that is a portion of the top epitaxial semiconductor layer 106. Therefore, the fin-type active region F1 may have the backside surface 106B having an improved flatness without a difference in surface roughness (e.g., a relatively uniform flatness with thickness deviation below a certain value) depending on positions in the backside surface 106B of the fin-type active region F1. Therefore, in a manufacturing process of an integrated circuit device having a BSPDN structure, when subsequent processes to a thinning process for reducing the thickness of the base substrate 110 are performed by using the fin-type active region F1 that is a portion of the top epitaxial semiconductor layer 106 remaining in a resulting product having undergone the thinning process, the backside surface 106B of the top epitaxial semiconductor layer 106 may provide uniform flatness on the entire surface thereof without a thickness deviation (e.g., a relatively uniform flatness with thickness deviation below a certain value) depending on positions in the top epitaxial semiconductor layer 106 remaining in the resulting product, thereby improving the stability in the manufacturing process of an integrated circuit device and/or improving the reliability of the integrated circuit device obtained as a result.

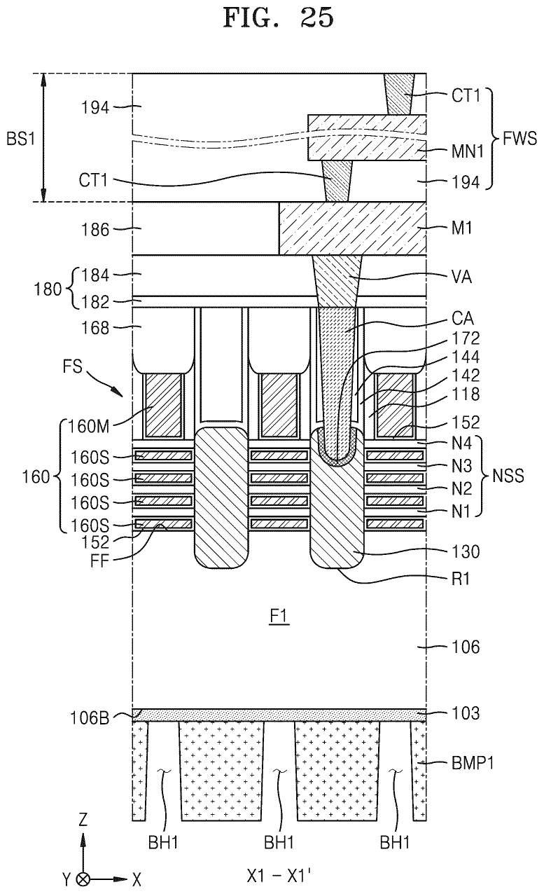

FIGS. 25 to 29 are cross-sectional views respectively illustrating a sequence of processes of a method of manufacturing the integrated circuit device 100 shown in FIG. 7. FIGS. 25 to 29 illustrate cross-sectional structures of a region corresponding to the cross-section taken along the line X1-X1′ of FIG. 7, respectively. In FIGS. 25 to 29, the same reference numerals as in FIGS. 2A to 24 denote the same members, respectively, and here, repeated descriptions thereof are omitted.

Referring to FIG. 25, the processes described with reference to FIGS. 8 to 16 may be performed. Next, in the resulting product having undergone the process of FIG. 16, a first backside mask pattern BMP1 may be formed on the bottom epitaxial semiconductor layer 103. Details of the process of forming the first backside mask pattern BMP1 are the same as those described with reference to FIG. 18.

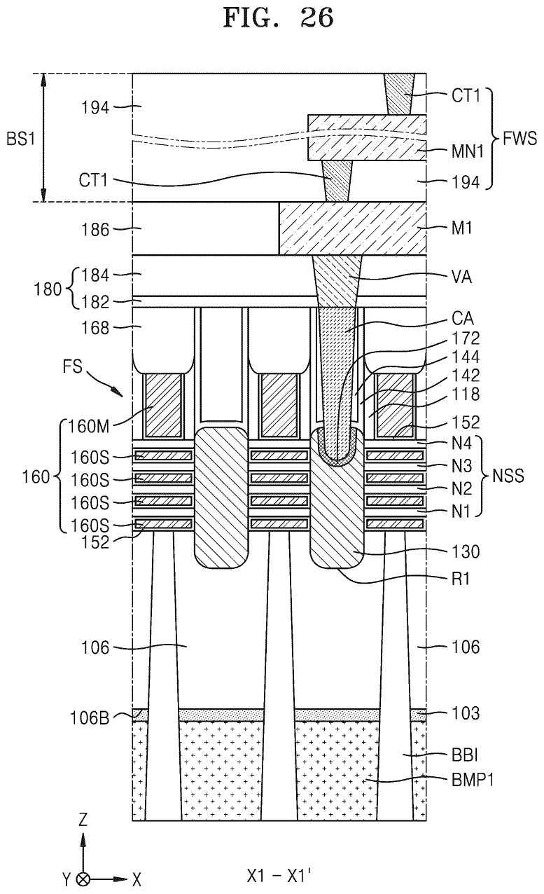

Referring to FIG. 26, in the resulting product of FIG. 25, a portion of each of the bottom epitaxial semiconductor layer 103 and the fin-type active region F1 may be etched by using the first backside mask pattern BMP1 as an etch mask in a similar manner to that described with reference to FIG. 19, thereby forming a plurality of vertical holes VCH extending in the vertical direction (the Z direction) toward the gate line 160. In some example embodiments, after the plurality of vertical holes VCH are formed, the gate dielectric film 152 may be exposed by each of the plurality of vertical holes VCH. Next, the plurality of backside bulk insulating films BBI may be formed to fill the plurality of vertical holes VCH and the plurality of line-shaped openings BH1.

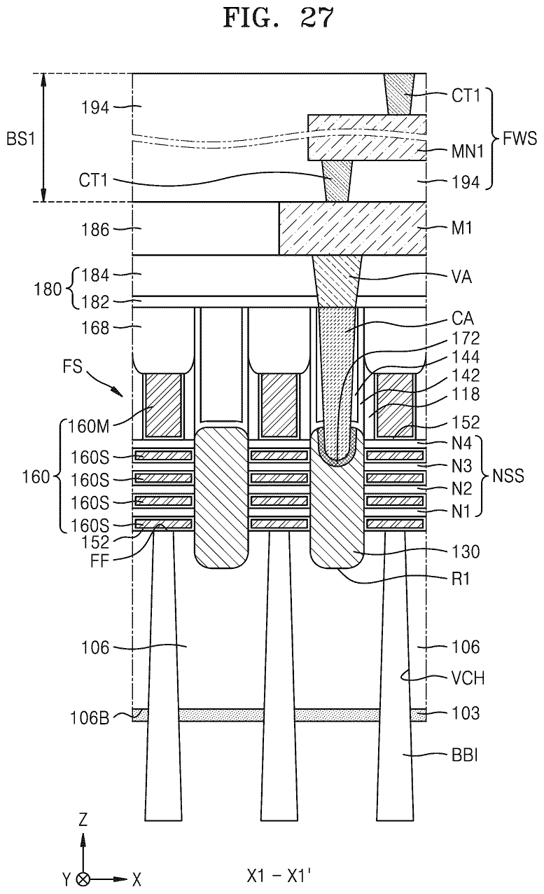

Referring to FIG. 27, in a similar manner to that described with reference to FIG. 20, the first backside mask pattern BMP1 may be removed from the resulting product of FIG. 26. As a result, the bottom epitaxial semiconductor layer 103 may be exposed between each of the plurality of backside bulk insulating films BBI.

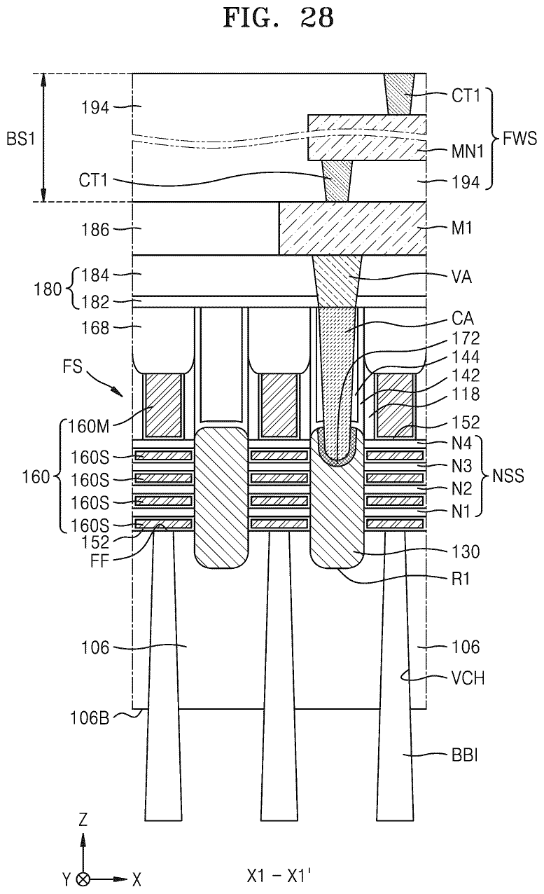

Referring to FIG. 28, in the resulting product of FIG. 27, the bottom epitaxial semiconductor layer 103 may be selectively removed by wet etching by using the difference in dopant concentration between the top epitaxial semiconductor layer 106 having a relatively low dopant concentration and the bottom epitaxial semiconductor layer 103 having a relatively high dopant concentration, thereby exposing the backside surface 106B of the top epitaxial semiconductor layer 106. Details of the process of selectively removing the bottom epitaxial semiconductor layer 103 by wet etching are the same as those described with reference to FIGS. 2F and 17.

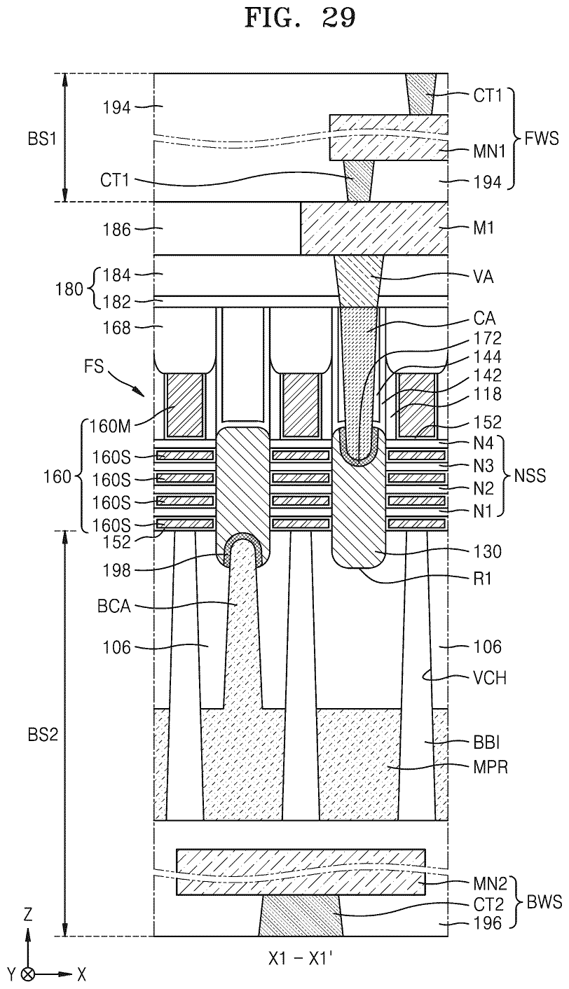

Referring to FIG. 29, the processes described with reference to FIGS. 21 to 24 are performed on the resulting product of FIG. 28, thereby forming a second BEOL structure BS2 including a backside via contact BCA, a backside power rail MPR, and a backside wiring structure BWS.

According to the method, described with reference to FIGS. 25 to 29, of manufacturing an integrated circuit device, similar to the descriptions made with reference to FIGS. 8 to 24, after the semiconductor substrate 102 is removed to perform a thinning process for reducing the thickness of the base substrate 110, the method includes a process of exposing the backside surface 106B of the top epitaxial semiconductor layer 106 by removing the bottom epitaxial semiconductor layer 103 through wet etching by using the difference in dopant concentration between the top epitaxial semiconductor layer 106 having a relatively low dopant concentration and the bottom epitaxial semiconductor layer 103 having a relatively high dopant concentration. For example, in the method, described with reference to FIGS. 25 to 29, of manufacturing an integrated circuit device, because the bottom epitaxial semiconductor layer 103 is removed by wet etching after the process of forming the plurality of vertical holes VCH to pass through the fin-type active region F1 including a portion of the top epitaxial semiconductor layer 106 and the process of forming the plurality of backside bulk insulating films BBI to respectively fill the plurality of vertical holes VCH are performed, the backside surface 106B of the top epitaxial semiconductor layer 106 may be protected by the bottom epitaxial semiconductor layer 103 while the plurality of vertical holes VCH are being formed in the top epitaxial semiconductor layer 106. Therefore, the possibility of surface damage, which the top epitaxial semiconductor layer 106 may suffer from during the formation of the plurality of vertical holes VCH in the top epitaxial semiconductor layer 106, due to an etching process atmosphere may be reduced or prevented by the bottom epitaxial semiconductor layer 103, and the top epitaxial semiconductor layer 106 may have the backside surface 106B having an improved flatness without a difference in surface roughness (e.g., a relatively uniform flatness with thickness deviation below a certain value) depending on positions in the top epitaxial semiconductor layer 106. In a resulting product in which the plurality of backside bulk insulating films BBI are formed, when subsequent processes are performed by using the top epitaxial semiconductor layer 106, the backside surface 106B of the top epitaxial semiconductor layer 106 may provide uniform flatness on the entire surface thereof without a thickness deviation (e.g., a relatively uniform flatness with thickness deviation below a certain value) depending on positions in the top epitaxial semiconductor layer 106 remaining in the resulting product, thereby improving the stability in a manufacturing process of an integrated circuit device and/or improving the reliability of the integrated circuit device obtained as a result.

While the inventive concepts have been particularly shown and described with reference to some example embodiments thereof, it will be understood that various changes in form and details may be made therein without departing from the spirit and scope of the following claims.

What is claimed is:

1. A method of manufacturing an integrated circuit device, the method comprising:
forming a base substrate with a structure that comprises
a semiconductor substrate having a first dopant concentration,
a bottom epitaxial semiconductor layer integrally connected to the semiconductor substrate, the bottom epitaxial semiconductor layer having a second dopant concentration greater than the first dopant concentration, and
a top epitaxial semiconductor layer integrally connected to the bottom epitaxial semiconductor layer and having a third dopant concentration less than the second dopant concentration, wherein the semiconductor substrate, the bottom epitaxial semiconductor layer, and the top epitaxial semiconductor layer are sequentially stacked in a vertical direction;
forming a front-end-of-line (FEOL) structure on a frontside surface of the top epitaxial semiconductor layer;
forming a first back-end-of-line (BEOL) structure on the FEOL structure such that the first BEOL structure is apart from the base substrate in the vertical direction with the FEOL structure therebetween;
removing the semiconductor substrate from the base substrate to expose the bottom epitaxial semiconductor layer; and
forming a second BEOL structure to be apart from the first BEOL structure in the vertical direction with the FEOL structure therebetween by performing a backside process that comprises
removing the bottom epitaxial semiconductor layer by wet etching to expose the top epitaxial semiconductor layer, and
patterning the top epitaxial semiconductor layer.

2. The method of claim 1, wherein the forming the base substrate comprises:
forming the bottom epitaxial semiconductor layer such that the second dopant concentration
has a maximum value in an edge portion of the bottom epitaxial semiconductor layer that is close to the semiconductor substrate in the vertical direction, and
gradually decreases toward the top epitaxial semiconductor layer in the vertical direction from the edge portion of the bottom epitaxial semiconductor layer.

3. The method of claim 1, wherein, in the forming the base substrate, each of the semiconductor substrate, the bottom epitaxial semiconductor layer, and the top epitaxial semiconductor layer comprises silicon (Si) doped with a p-type dopant.

4. The method of claim 1, wherein, in the forming the base substrate, each of the semiconductor substrate, the bottom epitaxial semiconductor layer, and the top epitaxial semiconductor layer comprises silicon (Si) doped with an n-type dopant.

5. The method of claim 1, wherein, in the forming of the base substrate,
each of the semiconductor substrate, the bottom epitaxial semiconductor layer, and the top epitaxial semiconductor layer comprises doped silicon (Si), and
the base substrate does not comprise germanium (Ge).

6. The method of claim 1, wherein
the removing the bottom epitaxial semiconductor layer by wet etching comprises exposing a backside surface of the top epitaxial semiconductor layer;
the patterning the top epitaxial semiconductor layer comprises, subsequent to the removing of the bottom epitaxial semiconductor layer by wet etching, forming a plurality of holes in the top epitaxial semiconductor layer to expose portions of the FEOL structure by etching a portion of the top epitaxial semiconductor layer from the backside surface of the top epitaxial semiconductor layer; and
forming a contact structure to fill each of the plurality of holes.

7. The method of claim 1, wherein the forming the second BEOL structure comprises:
forming a plurality of holes in the top epitaxial semiconductor layer to expose portions of the FEOL structure by etching a portion of each of the bottom epitaxial semiconductor layer and the top epitaxial semiconductor layer from an exposed surface of the bottom epitaxial semiconductor layer, while a backside surface of the top epitaxial semiconductor layer is covered by the bottom epitaxial semiconductor layer;
exposing the backside surface of the top epitaxial semiconductor layer by removing, by wet etching, the bottom epitaxial semiconductor layer remaining on the top epitaxial semiconductor layer from a resulting product in which the plurality of holes are formed; and
forming a plurality of contact structures to fill the plurality of holes, respectively.

8. The method of claim 1, further comprising:
after the forming the first BEOL structure and before the removing the semiconductor substrate, bonding a sustain wafer onto the first BEOL structure,
wherein the removing the semiconductor substrate and the forming the second BEOL structure are performed while the first BEOL structure is bonded to the sustain wafer.

9. The method of claim 1, wherein
the forming the base substrate comprises forming the bottom epitaxial semiconductor layer such that
the second dopant concentration in the bottom epitaxial semiconductor layer has a concentration gradient with a maximum value in a central portion of the bottom epitaxial semiconductor layer based on a total thickness of the bottom epitaxial semiconductor layer in the vertical direction, and
the second dopant concentration in edge portions of the bottom epitaxial semiconductor layer gradually decreases away from the central portion of the bottom epitaxial semiconductor layer towards edge portions of the bottom epitaxial semiconductor layer, the edge portions being close to the semiconductor substrate and the top epitaxial semiconductor layer, respectively, and
in the bottom epitaxial semiconductor layer, a thickness of the central portion, in which the second dopant concentration has the maximum value, in the vertical direction is greater than a thickness of each of the edge portions in the vertical direction.

10. The method of claim 1, wherein
the forming the base substrate comprises forming the bottom epitaxial semiconductor layer such that the second dopant concentration in the bottom epitaxial semiconductor layer has a variable concentration gradient in the vertical direction, and
in the bottom epitaxial semiconductor layer, a first distance in the vertical direction from a portion having a maximum value of the second dopant concentration to the top epitaxial semiconductor layer is greater than a second distance from the portion having the maximum value of the second dopant concentration to the semiconductor substrate.

11. The method of claim 1, wherein
the forming the FEOL structure comprises
forming a fin-type active region by etching a portion of the top epitaxial semiconductor layer, the fin-type active region comprising another portion of the top epitaxial semiconductor layer, and
forming a source/drain region on the fin-type active region, and the forming of the second BEOL structure comprises
removing the bottom epitaxial semiconductor layer by wet etching to expose a backside surface of the fin-type active region,
subsequently, forming a via hole in the fin-type active region to expose a portion of the source/drain region by etching a portion of the fin-type active region from the backside surface of the fin-type active region, and
forming a contact structure to fill the via hole, the contact structure being connected to the source/drain region.

12. The method of claim 1, wherein
the forming the FEOL structure comprises
forming a fin-type active region by etching a portion of the top epitaxial semiconductor layer, the fin-type active region comprising another portion of the top epitaxial semiconductor layer, and
forming, on or over the fin-type active region, a gate line, a gate dielectric film surrounding the gate line, and a source/drain region, and
the forming of the second BEOL structure comprises
forming a vertical hole in the fin-type active region to extend in the vertical direction toward the gate line by etching a portion of each of the bottom epitaxial semiconductor layer and the fin-type active region from an exposed surface of the bottom epitaxial semiconductor layer, while a backside surface of the fin-type active region is covered by the bottom epitaxial semiconductor layer,
forming a backside bulk insulating film to fill the vertical hole, and
exposing the backside surface of the fin-type active region by removing, by wet etching, the bottom epitaxial semiconductor layer remaining on the backside surface of the fin-type active region from a resulting product in which the backside bulk insulating film is formed.

13. A method of manufacturing an integrated circuit device, the method comprising:
forming a base substrate with a structure that comprises
a semiconductor substrate having a first dopant concentration,
a bottom epitaxial semiconductor layer having a second dopant concentration greater than the first dopant concentration, and
a top epitaxial semiconductor layer having a third dopant concentration less than the second dopant concentration, wherein the semiconductor substrate, the bottom epitaxial semiconductor layer, and the top epitaxial semiconductor layer are sequentially stacked in a vertical direction;
forming a fin-type active region by etching a portion of the top epitaxial semiconductor layer, the fin-type active region comprising another portion of the top epitaxial semiconductor layer;
forming a front-end-of-line (FEOL) structure on the fin-type active region, the FEOL structure comprising a gate line and a source/drain region;
forming a first back-end-of-line (BEOL) structure on the FEOL structure such that the first BEOL structure is apart from the base substrate in the vertical direction with the FEOL structure therebetween;
removing the semiconductor substrate from the base substrate to expose the bottom epitaxial semiconductor layer; and
forming a second BEOL structure to be apart from the first BEOL structure in the vertical direction with the FEOL structure therebetween by performing a backside process that comprises
removing the bottom epitaxial semiconductor layer by wet etching to expose a backside surface of the fin-type active region, and
etching at least a portion of the fin-type active region.

14. The method of claim 13, wherein the forming the base substrate comprises:
forming the bottom epitaxial semiconductor layer such that the second dopant concentration
has a maximum value in an edge portion of the bottom epitaxial semiconductor layer that is close to the semiconductor substrate in the vertical direction, and
gradually decreases toward the top epitaxial semiconductor layer in the vertical direction from the edge portion of the bottom epitaxial semiconductor layer.

15. The method of claim 13, wherein, in the forming of the base substrate,
each of the semiconductor substrate, the bottom epitaxial semiconductor layer, and the top epitaxial semiconductor layer comprises doped silicon (Si), and
the base substrate does not comprise germanium (Ge).

16. The method of claim 13, further comprising:
after the forming the first BEOL structure and before the removing the semiconductor substrate, bonding a sustain wafer onto the first BEOL structure,
wherein the removing the semiconductor substrate and the forming the second BEOL structure are performed while the first BEOL structure is bonded to the sustain wafer.

17. The method of claim 13, wherein the forming the second BEOL structure comprises:
after the removing the bottom epitaxial semiconductor layer, forming a via hole in the fin-type active region to expose a portion of the source/drain region by etching a portion of the fin-type active region from the backside surface of the fin-type active region; and
forming a contact structure to fill the via hole, the contact structure being connected to the source/drain region.

18. The method of claim 13, wherein the forming the second BEOL structure comprises:
forming a vertical hole in the fin-type active region to extend in the vertical direction toward the gate line by etching a portion of each of the bottom epitaxial semiconductor layer and the fin-type active region from an exposed surface of the bottom epitaxial semiconductor layer, while the backside surface of the fin-type active region is covered by the bottom epitaxial semiconductor layer;
forming a backside bulk insulating film to fill the vertical hole; and
exposing the backside surface of the fin-type active region by removing, by wet etching, the bottom epitaxial semiconductor layer remaining on the backside surface of the fin-type active region from a resulting product in which the backside bulk insulating film is formed.

19. A method of manufacturing an integrated circuit device, the method comprising:
forming a base substrate that comprises
a Si substrate having a first dopant concentration,
a bottom epitaxial Si layer integrally connected to the Si substrate and having a second dopant concentration greater than the first dopant concentration, and
a top epitaxial Si layer without germanium (Ge), the top epitaxial Si layer being integrally connected to the bottom epitaxial Si layer and having a third dopant concentration less than the second dopant concentration;
forming a fin-type active region by etching a portion of the top epitaxial Si layer, the fin-type active region comprising another portion of the top epitaxial Si layer;
forming a front-end-of-line (FEOL) structure on the fin-type active region, the FEOL structure comprising a gate line and a source/drain region;
forming a first back-end-of-line (BEOL) structure on the FEOL structure such that the first BEOL structure is apart from the base substrate in a vertical direction with the FEOL structure therebetween;
bonding a sustain wafer onto the first BEOL structure;
removing the Si substrate from the base substrate to expose the bottom epitaxial Si layer while the first BEOL structure is bonded to the sustain wafer; and
forming a second BEOL structure to be apart from the first BEOL structure with the FEOL structure therebetween by performing a backside process that comprises
removing the bottom epitaxial Si layer by wet etching to expose a backside surface of the fin-type active region, and
etching at least a portion of the fin-type active region, while the first BEOL structure is bonded to the sustain wafer.

20. The method of claim 19, wherein the forming the base substrate comprises forming the bottom epitaxial Si layer such that the second dopant concentration has
a maximum value in an edge portion of the bottom epitaxial Si layer that is close to the Si substrate in the vertical direction, and
gradually decreases toward the top epitaxial Si layer in the vertical direction from the edge portion of the bottom epitaxial Si layer.
